(19) United States
(12) Patent Application Publication
(10) Pub. No.: US 2019/0081032 A1
(43) Pub. Date: Mar. 14, 2019

(54) SEMICONDUCTOR DEVICE

(71) Applicant: SOCIONEXT INC., Kanagawa (JP)

(72) Inventor: Kazuya OKUBO, Kanagawa (JP)

(21) Appl. No.: 16/184,695

(22) Filed: Nov. 8, 2018

Related U.S. Application Data
(63) Continuation of application No. PCT/JP2016/067384, filed on Jun. 10, 2016.

(51) Int. Cl. H01L 27/02; H01L 21/8238; H02H 9/04

(52) U.S. Cl. CPC H01L 27/0255; H02H 9/046; H01L 27/0292; H01L 21/823821

(57) ABSTRACT

First diodes being gate-type diodes are arrayed in a lateral direction, and each configured including a gate electrode and a p-type region and an n-type region on both sides of the gate electrode. Second diodes being STI-type diodes are arrayed in a longitudinal direction, and each configured including a p-type region and an n-type region and an STI element isolation structure between the p-type region and the n-type region. This configuration can surely prevent electrostatic breakdown even if a large surge current occurs while achieving lowered resistance and reduced occupied area of an ESD protection diode.

### CROSS-REFERENCE TO RELATED APPLICATION

This application is a continuation application of International Application PCT/JP2016/067384 filed on Jun. 10, 2016, and designated the U.S., the entire contents of which are incorporated herein by reference.

### FIELD

The present invention relates to a semiconductor device.

### BACKGROUND

In a semiconductor device, a large surge current may occur in assembling it into a semiconductor package and in handling it, causing electrostatic breakdown (ESD) in a transistor or the like. To prevent the ESD, an ESD protection diode is added to a circuit configuration. The occurring surge current flows not through a transistor or the like but through the ESD protection diode to thereby prevent the ESD of the transistor or the like.

Examples of the diode used as the ESD protection diode are roughly classified into two kinds such as a so-called gate-type diode and an STI-type diode.

The gate-type diode is a diode in which a gate is provided on a semiconductor layer (semiconductor substrate), a p-type region is formed on one side of the gate of the semiconductor layer and an n-type region is formed on the other side, and a portion under the gate of the semiconductor layer becomes a current path.

The STI-type diode is a diode in which a p-type region and an n-type region are formed in a semiconductor layer (semiconductor substrate), an STI element isolation structure is formed between the p-type region and the n-type region of the semiconductor layer, and a portion under the STI element isolation structure of the semiconductor layer becomes a current path.

Patent Document 1: U.S. Unexamined Patent Application Publication No. 2005/0275029

Patent Document 2: U.S. Pat. No. 9,093,492

Patent Document 3: U.S. Unexamined Patent Application Publication No. 2015/0214212

Patent Document 4: U.S. Unexamined Patent Application Publication No. 2015/0091056

Patent Document 5: U.S. Unexamined Patent Application Publication No. 2014/0217461

A large surge current momentarily flows through the ESD protection diode. Therefore, a lower voltage applied to the ESD protection diode is better, and the ESD protection diode is desirably to be low in resistance. With a request for microfabrication of the semiconductor device, the area of an active region also needs to be reduced. However, particularly in a gate-type diode of a three-dimensional structure, a discharge path in the active region under the gate is limited by the cross-sectional area of the active region, bringing about a problem of an increase in resistance due to the cross-sectional area decreasing accompanying the microfabrication of the semiconductor device.

To cope with a large surge current in the ESD protection diode, the ESD protection diode requires a relatively large occupied area. With the request for microfabrication of the semiconductor device, it becomes important to make a design for manufacturing (DFM) in consideration of the productivity, and it is required to arrange a dummy gate also in the ESD protection diode also from the viewpoint of the uniform element formation. However, since the active region is covered by the dummy gate in the STI-type diode, there is a problem of a decrease of an effective region as the diode to fail to ensure a sufficient occupied area.

### SUMMARY

As described above, even if any of the gate-type diode and the STI-type diode is used as the ESD protection diode, there occurs a problem such as an increase in resistance and a waste in terms of layout.

One aspect of the semiconductor device includes: a semiconductor layer; a gate; a first insulator in contact with the gate and the semiconductor layer; a second insulator formed in the semiconductor layer; a first diode including, in a current path, a portion of the semiconductor layer in contact with the first insulator; and a second diode including, in a current path, a portion of the semiconductor layer in contact with the second insulator, wherein the first diode and the second diode are connected in parallel.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a schematic view illustrating a method for manufacturing a semiconductor device according to a first embodiment;

FIG. 1B is a schematic view illustrating, subsequent to FIG. 1A, the method for manufacturing the semiconductor device according to the first embodiment;

FIG. 1C is a schematic view illustrating, subsequent to FIG. 1B, the method for manufacturing the semiconductor device according to the first embodiment;

FIG. 2A is a schematic view illustrating, subsequent to FIG. 1C, the method for manufacturing the semiconductor device according to the first embodiment;

FIG. 2B is a schematic view illustrating, subsequent to FIG. 1C, the method for manufacturing the semiconductor device according to the first embodiment;

FIG. 2C is a schematic view illustrating, subsequent to FIG. 1C, the method for manufacturing the semiconductor device according to the first embodiment;

FIG. 3A is a schematic view illustrating, subsequent to FIG. 2A, the method for manufacturing the semiconductor device according to the first embodiment;

FIG. 3B is a schematic view illustrating, subsequent to FIG. 2B, the method for manufacturing the semiconductor device according to the first embodiment;

FIG. 3C is a schematic view illustrating, subsequent to FIG. 2C, the method for manufacturing the semiconductor device according to the first embodiment;

FIG. 4A is a schematic view illustrating, subsequent to FIG. 3A, the method for manufacturing the semiconductor device according to the first embodiment;

FIG. 4B is a schematic view illustrating, subsequent to FIG. 3B, the method for manufacturing the semiconductor device according to the first embodiment;

FIG. 4C is a schematic view illustrating, subsequent to FIG. 3C, the method for manufacturing the semiconductor device according to the first embodiment;

FIG. 5A is a schematic view illustrating, subsequent to FIG. 4A, the method for manufacturing the semiconductor device according to the first embodiment;

FIG. 5B is a schematic view illustrating, subsequent to FIG. 4B, the method for manufacturing the semiconductor device according to the first embodiment;

FIG. 5C is a schematic view illustrating, subsequent to FIG. 4C, the method for manufacturing the semiconductor device according to the first embodiment;

FIG. 6A is a schematic view illustrating, subsequent to FIG. 5A, the method for manufacturing the semiconductor device according to the first embodiment;

FIG. 6B is a schematic view illustrating, subsequent to FIG. 5B, the method for manufacturing the semiconductor device according to the first embodiment;

FIG. 6C is a schematic view illustrating, subsequent to FIG. 5C, the method for manufacturing the semiconductor device according to the first embodiment;

FIG. 7A is a schematic view illustrating, subsequent to FIG. 6A, the method for manufacturing the semiconductor device according to the first embodiment;

FIG. 7B is a schematic view illustrating, subsequent to FIG. 6B, the method for manufacturing the semiconductor device according to the first embodiment;

FIG. 7C is a schematic view illustrating, subsequent to FIG. 6C, the method for manufacturing the semiconductor device according to the first embodiment;

FIG. 8 is a schematic view illustrating, subsequent to FIG. 7C, the method for manufacturing the semiconductor device according to the first embodiment;

FIG. 9A is a schematic view illustrating, subsequent to FIG. 8, the method for manufacturing the semiconductor device according to the first embodiment;

FIG. 9B is a schematic view illustrating, subsequent to FIG. 8, the method for manufacturing the semiconductor device according to the first embodiment;

FIG. 9C is a schematic view illustrating, subsequent to FIG. 8, the method for manufacturing the semiconductor device according to the first embodiment;

FIG. 10A is a schematic view illustrating a case where wirings in another aspect are formed in the method for manufacturing the semiconductor device according to the first embodiment;

FIG. 10B is a schematic view illustrating a case where wirings in another aspect are formed in the method for manufacturing the semiconductor device according to the first embodiment;

FIG. 11A is a schematic view illustrating, subsequent to FIG. 9B, the method for manufacturing the semiconductor device according to the first embodiment;

FIG. 11B is a schematic view illustrating, subsequent to FIG. 9A, the method for manufacturing the semiconductor device according to the first embodiment;

FIG. 12 is a schematic plan view illustrating a layout configuration of a diode formation region of the semiconductor device according to the first embodiment;

FIG. 13 is a schematic diagram illustrating a circuit configuration of the semiconductor device according to the first embodiment;

FIG. 14A is a schematic view illustrating a method for manufacturing a semiconductor device according to a second embodiment;

FIG. 14B is a schematic view illustrating, subsequent to FIG. 14A, the method for manufacturing the semiconductor device according to the second embodiment;

FIG. 15A is a schematic view illustrating, subsequent to FIG. 14B, the method for manufacturing the semiconductor device according to the second embodiment;

FIG. 15B is a schematic view illustrating, subsequent to FIG. 15A, the method for manufacturing the semiconductor device according to the second embodiment;

FIG. 16A is a schematic view illustrating, subsequent to FIG. 15B, the method for manufacturing the semiconductor device according to the second embodiment;

FIG. 16B is a schematic view illustrating, subsequent to FIG. 16A, the method for manufacturing the semiconductor device according to the second embodiment;

FIG. 17A is a schematic view illustrating, subsequent to FIG. 16B, the method for manufacturing the semiconductor device according to the second embodiment;

FIG. 17B is a schematic view illustrating, subsequent to FIG. 17A, the method for manufacturing the semiconductor device according to the second embodiment;

FIG. 18A is a schematic view illustrating, subsequent to FIG. 17B, the method for manufacturing the semiconductor device according to the second embodiment;

FIG. 18B is a schematic view illustrating, subsequent to FIG. 18A, the method for manufacturing the semiconductor device according to the second embodiment;

FIG. 19A is a schematic view illustrating, subsequent to FIG. 18B, the method for manufacturing the semiconductor device according to the second embodiment;

FIG. 19B is a schematic view illustrating, subsequent to FIG. 19A, the method for manufacturing the semiconductor device according to the second embodiment;

FIG. 20A is a schematic view illustrating, subsequent to FIG. 19B, the method for manufacturing the semiconductor device according to the second embodiment;

FIG. 20B is a schematic view illustrating, subsequent to FIG. 20A, the method for manufacturing the semiconductor device according to the second embodiment;

FIG. 21 is a schematic plan view illustrating a layout configuration of a diode formation region of the semiconductor device according to the second embodiment;

FIG. 22 is a schematic view illustrating a case where wirings in another aspect are formed in the method for manufacturing the semiconductor device according to the second embodiment;

FIG. 23A is a schematic view illustrating a method for manufacturing a semiconductor device according to a third embodiment;

FIG. 23B is a schematic view illustrating, subsequent to FIG. 23A, the method for manufacturing the semiconductor device according to the third embodiment;

FIG. 23C is a schematic view illustrating, subsequent to FIG. 23B, the method for manufacturing the semiconductor device according to the third embodiment;

FIG. 24A is a schematic view illustrating, subsequent to FIG. 23C, the method for manufacturing the semiconductor device according to the third embodiment;

FIG. 24B is a schematic view illustrating, subsequent to FIG. 24A, the method for manufacturing the semiconductor device according to the third embodiment;

FIG. 24C is a schematic view illustrating, subsequent to FIG. 24A, the method for manufacturing the semiconductor device according to the third embodiment;

FIG. 24D is a schematic view illustrating, subsequent to FIG. 24A, the method for manufacturing the semiconductor device according to the third embodiment;

FIG. 25A is a schematic view illustrating, subsequent to FIG. 24B, the method for manufacturing the semiconductor device according to the third embodiment;

FIG. 25B is a schematic view illustrating, subsequent to FIG. 24C, the method for manufacturing the semiconductor device according to the third embodiment;

FIG. 25C is a schematic view illustrating, subsequent to FIG. 24D, the method for manufacturing the semiconductor device according to the third embodiment;

FIG. 26A is a schematic view illustrating, subsequent to FIG. 25A, the method for manufacturing the semiconductor device according to the third embodiment;

FIG. 26B is a schematic view illustrating, subsequent to FIG. 25B, the method for manufacturing the semiconductor device according to the third embodiment;

FIG. 26C is a schematic view illustrating, subsequent to FIG. 25C, the method for manufacturing the semiconductor device according to the third embodiment;

FIG. 27A is a schematic view illustrating, subsequent to FIG. 26A, the method for manufacturing the semiconductor device according to the third embodiment;

FIG. 27B is a schematic view illustrating, subsequent to FIG. 26B, the method for manufacturing the semiconductor device according to the third embodiment;

FIG. 27C is a schematic view illustrating, subsequent to FIG. 26C, the method for manufacturing the semiconductor device according to the third embodiment;

FIG. 28A is a schematic view illustrating, subsequent to FIG. 27A, the method for manufacturing the semiconductor device according to the third embodiment;

FIG. 28B is a schematic view illustrating, subsequent to FIG. 27B, the method for manufacturing the semiconductor device according to the third embodiment;

FIG. 28C is a schematic view illustrating, subsequent to FIG. 27C, the method for manufacturing the semiconductor device according to the third embodiment;

FIG. 29A is a schematic view illustrating, subsequent to FIG. 28A, the method for manufacturing the semiconductor device according to the third embodiment;

FIG. 29B is a schematic view illustrating, subsequent to FIG. 28B, the method for manufacturing the semiconductor device according to the third embodiment;

FIG. 29C is a schematic view illustrating, subsequent to FIG. 28C, the method for manufacturing the semiconductor device according to the third embodiment;

FIG. 30A is a schematic view illustrating, subsequent to FIG. 29A, the method for manufacturing the semiconductor device according to the third embodiment;

FIG. 30B is a schematic view illustrating, subsequent to FIG. 29B, the method for manufacturing the semiconductor device according to the third embodiment;

FIG. 30C is a schematic view illustrating, subsequent to FIG. 29C, the method for manufacturing the semiconductor device according to the third embodiment;

FIG. 31A is a schematic view illustrating, subsequent to FIG. 30A, the method for manufacturing the semiconductor device according to the third embodiment;

FIG. 31B is a schematic view illustrating, subsequent to FIG. 30B, the method for manufacturing the semiconductor device according to the third embodiment;

FIG. 31C is a schematic view illustrating, subsequent to FIG. 30C, the method for manufacturing the semiconductor device according to the third embodiment;

FIG. 32A is a schematic view illustrating, subsequent to FIG. 31A, the method for manufacturing the semiconductor device according to the third embodiment;

FIG. 32B is a schematic view illustrating, subsequent to FIG. 31B, the method for manufacturing the semiconductor device according to the third embodiment;

FIG. 32C is a schematic view illustrating, subsequent to FIG. 31C, the method for manufacturing the semiconductor device according to the third embodiment;

FIG. 33A is a schematic view illustrating, subsequent to FIG. 32A, the method for manufacturing the semiconductor device according to the third embodiment;

FIG. 33B is a schematic view illustrating, subsequent to FIG. 32B, the method for manufacturing the semiconductor device according to the third embodiment;

FIG. 33C is a schematic view illustrating, subsequent to FIG. 32C, the method for manufacturing the semiconductor device according to the third embodiment;

FIG. 34 is a schematic view illustrating, subsequent to FIG. 33A, the method for manufacturing the semiconductor device according to the third embodiment;

FIG. 35 is a schematic view illustrating, subsequent to FIG. 34, the method for manufacturing the semiconductor device according to the third embodiment;

FIG. 36A is a schematic plan view illustrating a layout configuration of a diode formation region of the semiconductor device according to the third embodiment;

FIG. 36B is a schematic cross-sectional view illustrating the layout configuration of the diode formation region of the semiconductor device according to the third embodiment;

FIG. 37 is a schematic plan view illustrating another example of the layout configuration of the diode formation region of the semiconductor device according to the third embodiment; and

FIG. 38 is a schematic plan view illustrating another example of the layout configuration of the diode formation region of the semiconductor device according to the third embodiment.

### DESCRIPTION OF EMBODIMENTS

Hereinafter, embodiments of a semiconductor device including an ESD protection diode will be described in detail referring to the drawings.

### First Embodiment

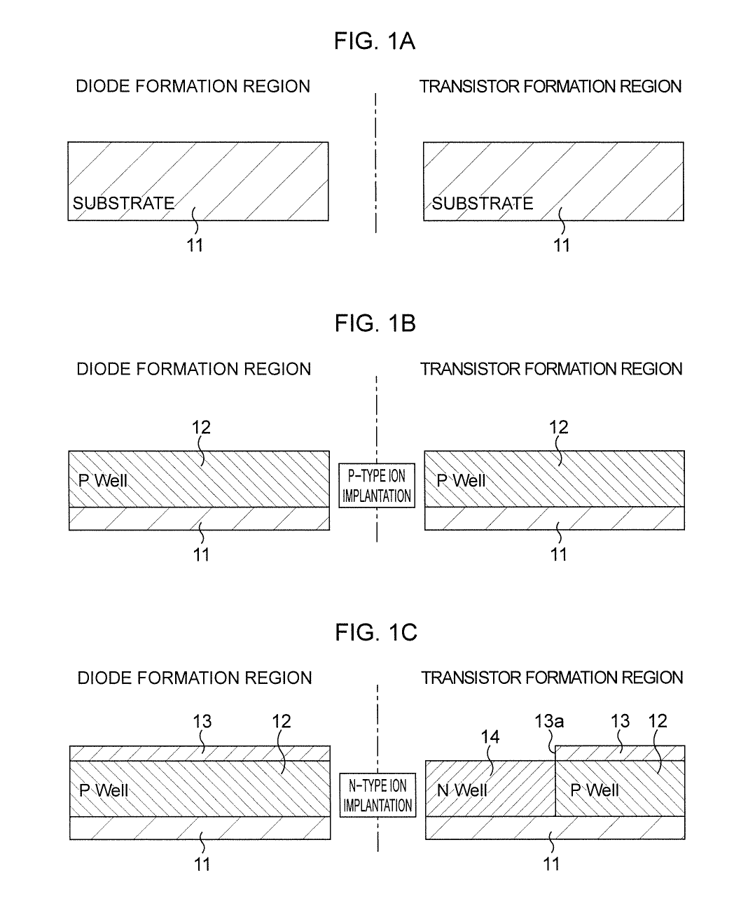

Hereinafter, a first embodiment will be described. FIG. 1A to FIG. 11 are schematic views illustrating a method for manufacturing a semiconductor device according to this embodiment.

First, as illustrated in FIG. 1A, for example, a silicon substrate 11 is prepared as a semiconductor substrate. In the following drawings, the left side illustrates a diode formation region and the right side illustrates a transistor formation region.

Subsequently, as illustrated in FIG. 1B, a p-type well 12 is formed.

In more detail, a p-type impurity is ion-implanted into a surface of the silicon substrate 11 to form the p-type well 12 in a surface layer of the silicon substrate 11.

Subsequently, as illustrated in FIG. 1C, an n-type well 14 is formed.

In more detail, first, a resist is applied to the surface of the silicon substrate 11 and processed by lithography. Thus, a resist mask 13 including an opening 13a exposing an n-type well formation region on the surface of the silicon substrate 11 is formed in the transistor formation region.

Next, an n-type impurity is ion-implanted to a portion of the silicon substrate 11 exposed from the opening 13a using the resist mask 13. Thus, an n-type well 14 adjacent to the p-type well 12 is formed in the surface layer of the silicon substrate 11 in the transistor formation region. The resist mask 13 is removed by wet treatment or ashing.

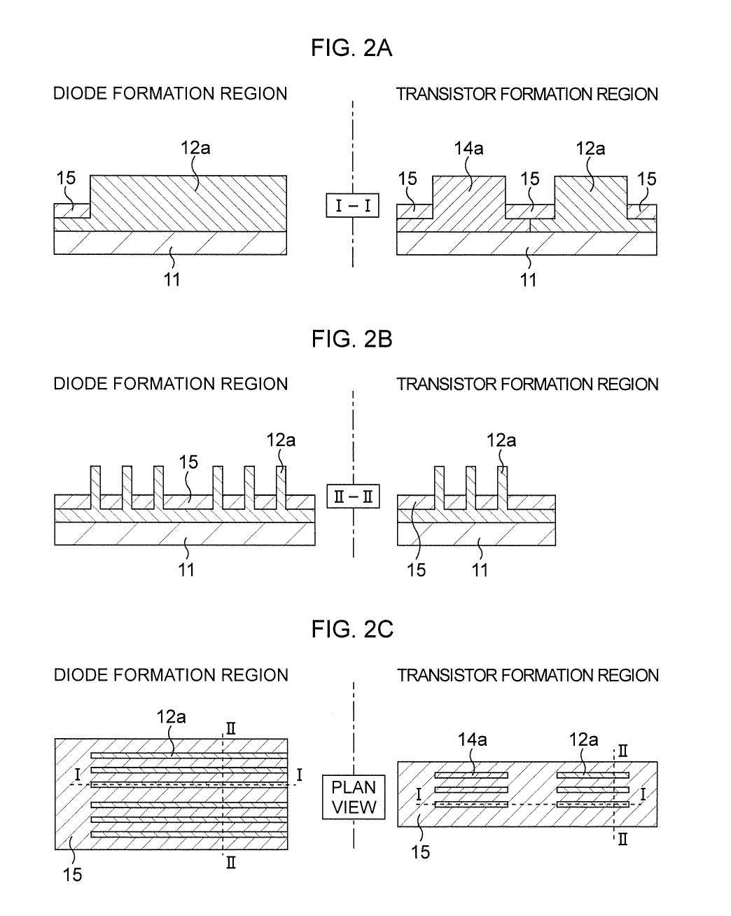

Subsequently, as illustrated in FIG. 2A to FIG. 2C, the silicon substrate 11 is processed into a shape of fins, and then an STI element isolation structure 15 is formed. FIG. 2C is a plan view, FIG. 2A is a cross-sectional view taken along a broken line I-I (lateral direction (X-direction)) in FIG. 2C, and FIG. 2B is a cross-sectional view taken along a broken line II-II (longitudinal direction (Y-direction)) in FIG. 2C.

In more detail, first, portions of the p-type well 12 and the n-type well 14 of the silicon substrate 11 are processed into a shape of fins arrayed in a shape of stripes by lithography and dry etching. A fin-shaped portion of the p-type well 12 is assumed to be a fin 12a, and a fin-shaped portion of the n-type well 14 is assumed to be a fin 14a. In the diode formation region in FIG. 2C, three fins 12a are arranged as a group on each of the upper side and the lower side in the drawing, but the number of fins 12a in the group is not limited to three. For example, the number of fins 12a in the group may be one or two, or may be, for example, seven larger than three. Further, as in the diode formation region, the number of each of the fins 12a and the fins 14a in the transistor region in FIG. 2C is not limited to three but may be an arbitrary number.

Next, an insulating film, for example, a silicon oxide film is deposited on the silicon substrate 11 by the CVD method or the like in a manner to be buried in spaces between the fins 12a, 14a. By planarizing the deposited silicon oxide film by etching back, the STI element isolation structure 15 is formed in which the silicon oxide film having a predetermined thickness is buried in the spaces between the fins 12a, 14a on the silicon substrate 11.

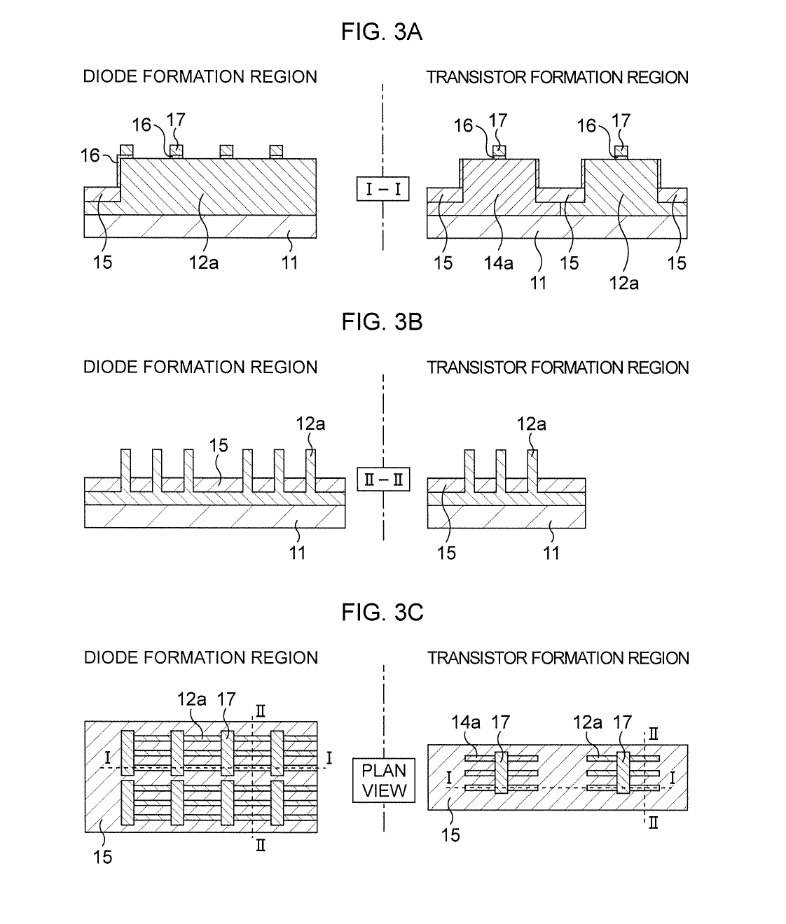

Subsequently, as illustrated in FIG. 3A to FIG. 3C, a dummy gate insulating film 16 and a dummy gate electrode 17 are formed. FIG. 3C is a plan view, FIG. 3A is a cross-sectional view taken along a broken line I-I in FIG. 3C, and FIG. 3B is a cross-sectional view taken along a broken line II-II in FIG. 3C.

In more detail, first, thermal oxidation is performed on the surface of the silicon substrate 11 to form a thermally oxidized film.

Next, a polycrystalline silicon film is deposited on the entire surface of the silicon substrate 11 by the CVD method or the like. The thermally oxidized film and the polycrystalline silicon film are processed into a gate shape by lithography and dry etching. Thus, the dummy gate insulating film 16 and the dummy gate electrode 17 are formed in a gate shape intersecting the longitudinal direction of the fins 12a, 14a.

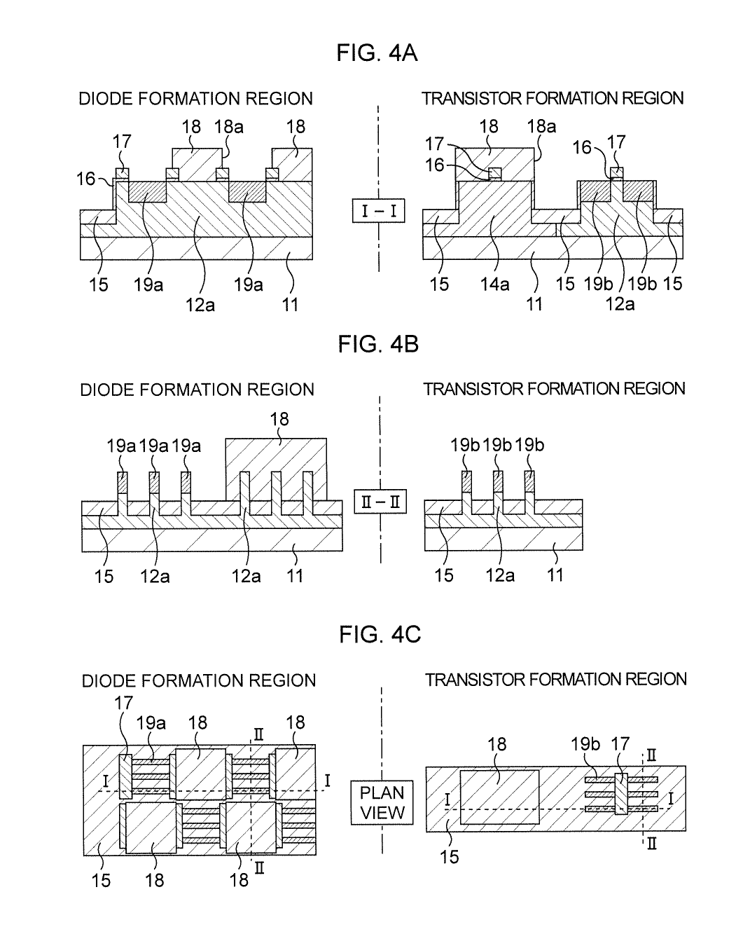

Subsequently, as illustrated in FIG. 4A to FIG. 4C, an n-type region 19a is formed in the diode formation region, and an n-type source/drain region 19b is formed in the transistor formation region. FIG. 4C is a plan view, FIG. 4A is a cross-sectional view taken along a broken line I-I in FIG. 4C, and FIG. 4B is a cross-sectional view taken along a broken line II-II in FIG. 4C.

In more detail, first, a resist is applied to the surface of the silicon substrate 11 and processed by lithography. Thus, a resist mask 18 is formed which includes an opening 18a exposing a formation site for the n-type region in the fin 12a in the diode formation region, and includes an opening 18a exposing a formation site for the n-type source/drain region in the fin 12a in the transistor formation region.

Next, an n-type impurity is ion-implanted to a portion of the fin 12a exposed from the opening 18a using the resist mask 18. The ion implantation is performed under a condition to achieve a concentration higher than an n-type impurity concentration in the n-type well 14. Thus, the n-type region 19a is formed in the fin 12a in the diode formation region, and the n-type source/drain region 19b is formed in the fin 12a in the transistor formation region. The resist mask 18 is removed by wet treatment or ashing.

Note that instead of forming the n-type region 19a and the n-type source/drain region 19b, a part of the fin 12a may be removed and an n-type semiconductor layer may be epitaxially grown.

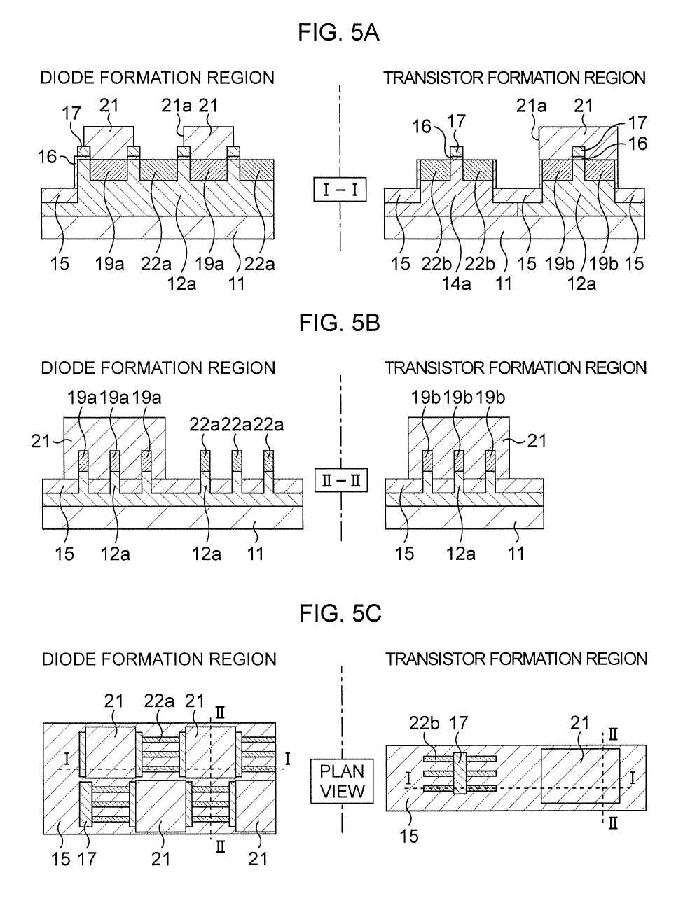

Subsequently, as illustrated in FIG. 5A to FIG. 5C, a p-type region 22a is formed in the diode formation region, and a p-type source/drain region 22b is formed in the transistor formation region. FIG. 5C is a plan view, FIG. 5A is a cross-sectional view taken along a broken line I-I in FIG. 5C, and FIG. 5B is a cross-sectional view taken along a broken line II-II in FIG. 5C.

In more detail, first, a resist is applied to the surface of the silicon substrate 11 and processed by lithography. Thus, a resist mask 21 is formed which includes an opening 21a exposing a formation site for the p-type region in the fin 12a in the diode formation region, and includes an opening 21a exposing a formation site for the p-type source/drain region in the fin 14a in the transistor formation region.

Next, a p-type impurity is ion-implanted to portions of the fins 12a, 14a exposed from the openings 21a using the resist mask 21. The ion implantation is performed under a condition to achieve a concentration higher than a p-type impurity concentration in the p-type well 12. Thus, the n-type region 22a is formed in the fin 12a in the diode formation region, and the p-type source/drain region 22b is formed in the fin 14a in the transistor formation region. The resist mask 21 is removed by wet treatment or ashing.

Note that instead of forming the p-type region 22a and the p-type source/drain region 22b, parts of the fins 12a, 14a may be removed and a p-type semiconductor layer may be epitaxially grown.

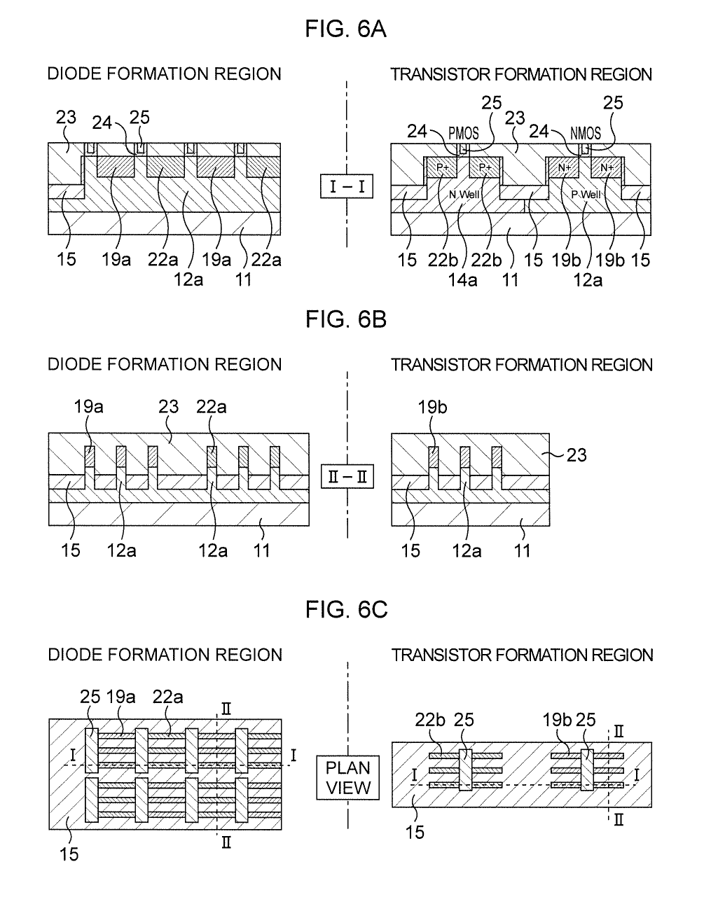

Subsequently, as illustrated in FIG. 6A to FIG. 6C, a gate insulating film 24 and a gate electrode 25 are formed. FIG. 6C is a plan view, FIG. 6A is a cross-sectional view taken along a broken line I-I in FIG. 6C, and FIG. 6B is a cross-sectional view taken along a broken line II-II in FIG. 6C. In FIG. 6C, the illustration of an interlayer insulating film 23 is omitted.

In more detail, first, an insulating film covering the entire surface of the silicon substrate 11, for example, a silicon oxide film is deposited by the CVD method or the like to form the interlayer insulating film 23. The interlayer insulating film 23 is planarized by the chemical mechanical polishing (CMP) method until the upper surface of the dummy gate electrode 17 is exposed. Thereafter, the dummy gate insulating film 16 and the dummy gate electrode 17 are selectively removed, for example, by wet etching.

Next, in an opening formed in the interlayer insulating film 23 by removing the dummy gate insulating film 16 and the dummy gate electrode 17, the gate insulating film 24 and the gate electrode 25 are formed. The gate insulating film 24 is formed using a high dielectric constant material, and the gate electrode 25 is formed using a metal material.

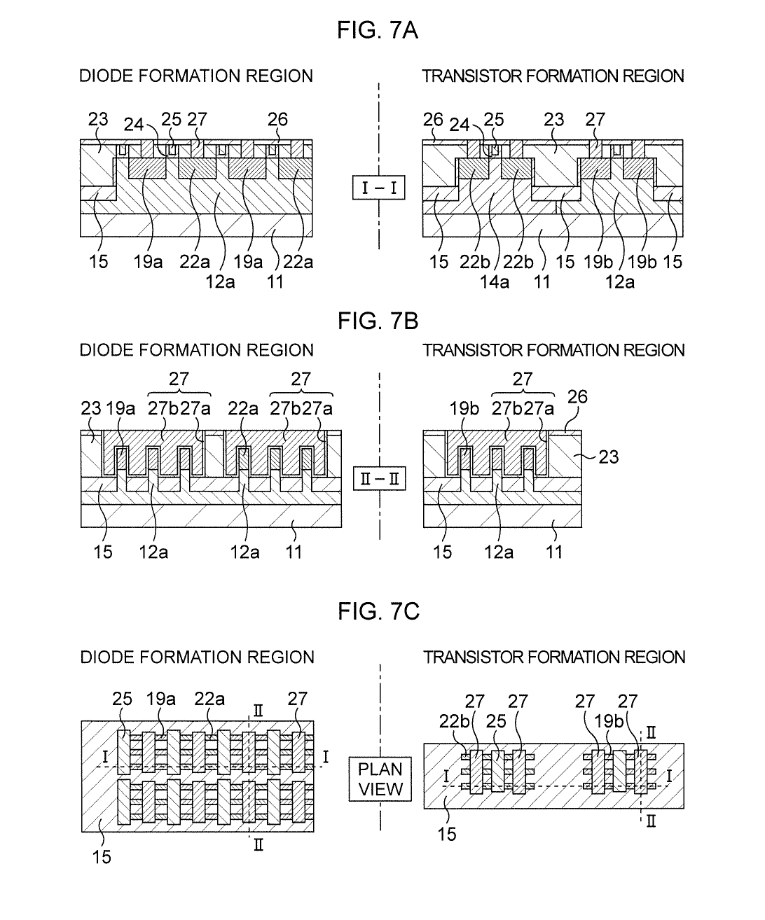

Subsequently, as illustrated in FIG. 7A to FIG. 7C, a local interconnect 27 is formed. FIG. 7C is a plan view, FIG. 7A is a cross-sectional view taken along a broken line I-I in FIG. 7C, and FIG. 7B is a cross-sectional view taken along a broken line II-II in FIG. 7C. In FIG. 7C, the illustration of the interlayer insulating films 23, 26 is omitted.

In more detail, first, an insulating film, for example, a silicon oxide film is deposited on the interlayer insulating film 23 by the CVD method or the like to form the interlayer insulating film 26.

Next, the interlayer insulating films 23, 26 are processed by lithography and dry etching. In the diode formation region, openings exposing parts of the surfaces of the n-type regions 19a, 22a are formed in the interlayer insulating films 23, 26. In the transistor formation region, openings exposing parts of the surfaces of the n-type source/drain regions 19b, 22b are formed in the interlayer insulating films 23, 26, and an opening exposing a part of the surface of the gate electrode 25 is formed in the interlayer insulating film 26.

Next, a metal material, for example, tungsten 27b is deposited on the interlayer insulating film 26 using titanium or titanium nitride 27a as a base in a manner to be buried in the openings. The deposited titanium or titanium nitride 27a and tungsten 27b are planarized by the CMP method until the upper surface of the interlayer insulating film 26 is exposed. Thus, the local interconnect 27 connected to the n-type region 19a or 22a is formed in the diode formation region. The local interconnect 27 connected to the n-type source/drain region 19b or 22b and the gate electrode 25 is formed in the transistor formation region.

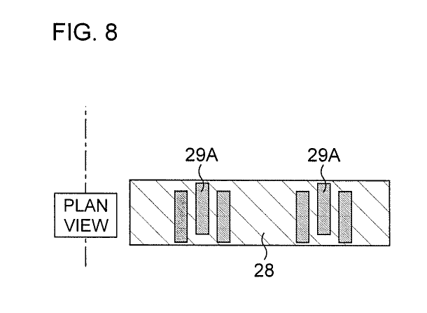

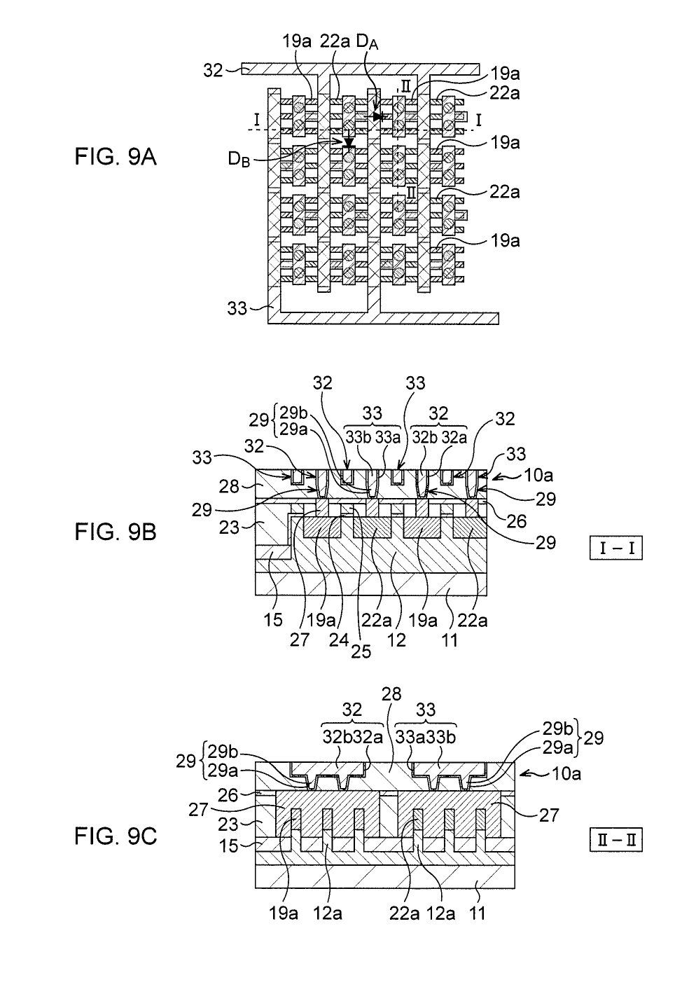

Subsequently, as illustrated in FIG. 8, and FIG. 9A to FIG. 9C, a first wiring layer 10a is formed. FIG. 9A is a plan view of the diode formation region, and FIG. 8 is a plan view of the transistor formation region. FIG. 9B is a cross-sectional view taken along a broken line I-I in FIG. 9A, and FIG. 9C is a cross-sectional view taken along a broken line II-II in FIG. 9A. In FIG. 9A, the illustration of the interlayer insulating films 23, 26, 28 and so on is omitted.

In this embodiment, the first wiring layer 10a is formed using a so-called dual damascene method in the diode formation region. In more detail, first, the interlayer insulating film 28 of, for example, a silicon oxide film is processed by lithography and dry etching to form a wiring trench and a composite trench, which is composed of integrated via hole and wiring trench, in the interlayer insulating film 28.

Next, a metal material, for example, copper using tantalum nitride as a base is deposited on the interlayer insulating film 28 in a manner to be buried in the wiring trench and the composite trench. The tantalum nitride and copper to be formed are tantalum nitride 32a (or tantalum nitride 33a) and copper 32b (or copper 33b) for the wiring trench. The tantalum nitride and copper to be formed are integrally formed tantalum nitride 32a and tantalum nitride 29a (or tantalum nitride 33a and tantalum nitride 29a) and integrally formed copper 32b and copper 29b (or copper 33b and copper 29b) for the composite trench. The deposited tantalum nitride and copper are planarized by the CMP method until the upper surface of the interlayer insulating film 28 is exposed. Thus, the first wiring layer 10a including the wiring 32 (or the wiring 33) and a wiring structure in which the wiring 32 and the via 29 are integrally formed (or a wiring structure in which the wiring 33 and the via 29 are integrally formed), is formed in the interlayer insulating film 28.

In the transistor formation region, a wiring 29A is formed simultaneously with the via 29 in the interlayer insulating film 28, and the surface of the wiring 29A is exposed to the surface of the interlayer insulating film 28 as illustrated in FIG. 8.

As illustrated in FIG. 9A, the wiring 32 and the above-described wiring structure are configured such that a portion extending above a plurality of gate electrodes 25 arrayed in the longitudinal direction, a portion connected to a contact plug 29 on the local interconnect 27 on both sides of which the n-type region 19a is arranged, and a portion connecting both the portions are integrally formed. The wiring 33 and the above-described wiring structure are configured such that a portion extending above the plurality of gate electrodes 25 arrayed in the longitudinal direction, a portion connected to the contact plug 29 on the local interconnect 27 on both sides of which the p-type region 22a is arranged, and a portion connecting both the portions are integrally formed.

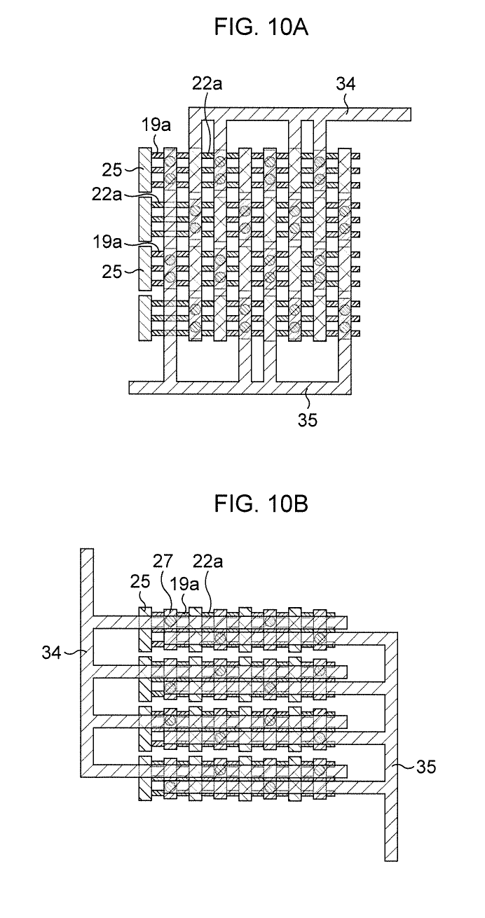

In this embodiment, in place of the layout as in FIG. 9A, a layout as in FIG. 10A may be configured. Also in this case, the dual damascene method is used as in the above. In the layout in FIG. 10A, the gate electrodes 25 and the local interconnects 27 in one row in the lateral direction are laid out to be shifted by a half pitch every other row. In this case, a part of the n-type region 19a and a part of the p-type region 22a are alternately arranged along the longitudinal direction. Configuring the layout makes it possible to form wirings 34, 35 in a shape extending only in one direction (here, the longitudinal direction). More specifically, the wirings 34, 35 extend, connected to a portion above the plurality of gate electrodes 25 and local interconnects 27 alternately arrayed in the longitudinal direction. This configuration facilitates exposure to light at pattering of the wirings (easy to adopt double patterning).

In FIG. 10A, the wirings 34, 35 in the lateral direction connecting the wirings 34, 35 in the longitudinal direction on the diodes respectively are illustrated but, for example, the wirings 34, 35 in the longitudinal direction may be arranged in a first layer of the multilayer wiring structure, and the wirings 34, 35 in the lateral direction may be arranged in a second layer of the multilayer wiring structure. The wirings 34, 35 in the first layer may be connected with the wirings 34, 35 in the second layer respectively through the vias. Forming the wirings as above facilitates achieving, for example, the multilayer wiring structure in which the wiring layer including the wirings extending in the lateral direction and the wiring layer including the wirings extending in the longitudinal direction are, for example, alternately layered. Therefore, the double patterning is easily adopted at the patterning of the wirings in each wiring layer.

Besides, it is conceivable to configure a layout as in FIG. 10B. In this case, the vias 29 are arranged to be shifted in the longitudinal direction (Y-direction) for each of conductivity types such as the p-type and the n-type, the vias 29 for each of the conductivity types are connected by the wirings 34, 35 extending in the lateral direction, and the wirings 34, 35 extend in the longitudinal direction. This configuration also facilitates exposure to light at pattering of the wirings (easy to adopt double patterning). In this case, the extending portion in the lateral direction and the extending portion in the longitudinal direction of the wirings 34, 35 may be formed as different layers.

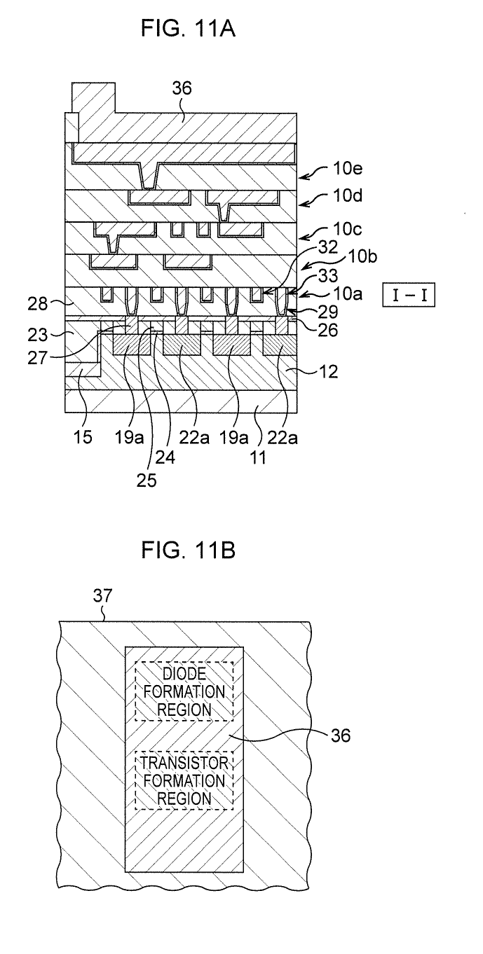

Thereafter, a plurality of wiring layers are formed to be layered and a connection pad 36 is formed on the uppermost layer as illustrated in FIG. 11A.

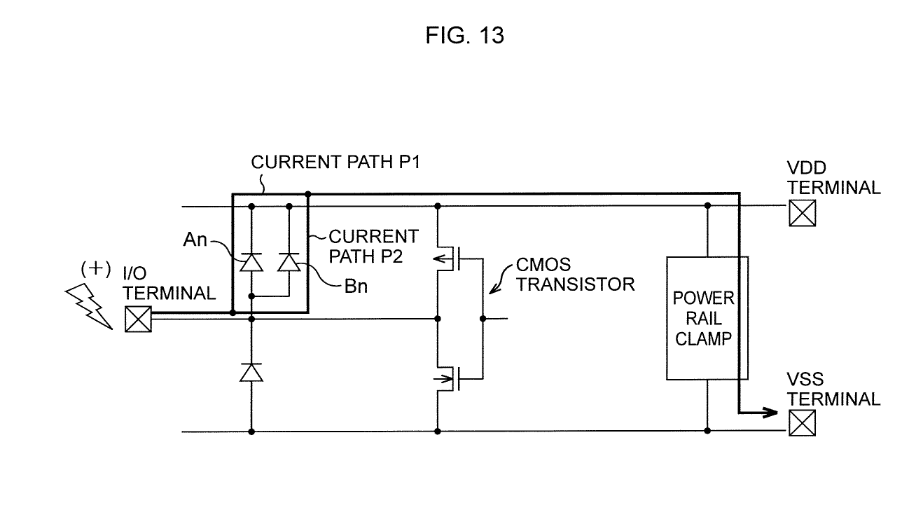

In more detail, a plurality of layers, for example, four (a second wiring layer 10b, a third wiring layer 10c, a fourth wiring layer 10d, a fifth wiring layer 10e) are layered on the first wiring layer 10a into the multilayer wiring structure. On the uppermost layer, the connection pad 36 made of aluminum or the like as a material is formed which is connected with the multilayer wiring structure. Here, the connection pad 36 is arranged to include the diode formation region and the transistor formation region in a plan view above the diode formation region and the transistor formation region as illustrated in FIG. 11B. In FIG. 11B, an outer peripheral portion of a semiconductor chip is indicated by a numeral 37. Note that the number of wiring layers is not limited to four, but may be more than that, for example, 10 or more. Further, a first diode Da and a second diode Db in the diode formation region may be electrically connected to the connection pad 36 thereabove as in the circuit configuration diagram in FIG. 13.

Thus, the semiconductor device according to this embodiment is formed.

In this embodiment, a first diode D_{A} and a second diode D_{B} are formed as the ESD protection diodes as in FIG. 9A in the diode formation region, and they are connected in parallel. In the transistor formation region, a PMOS transistor and an NMOS transistor are formed.

The first diode D_{A} is a gate-type diode including the gate electrode 25 and having a current path formed in the fin 12a near the gate electrode 25. The second diode D_{B} is an STI-type diode including an STI element isolation structure 15 and having a current path formed in the fin 12a near the STI element isolation structure 15.

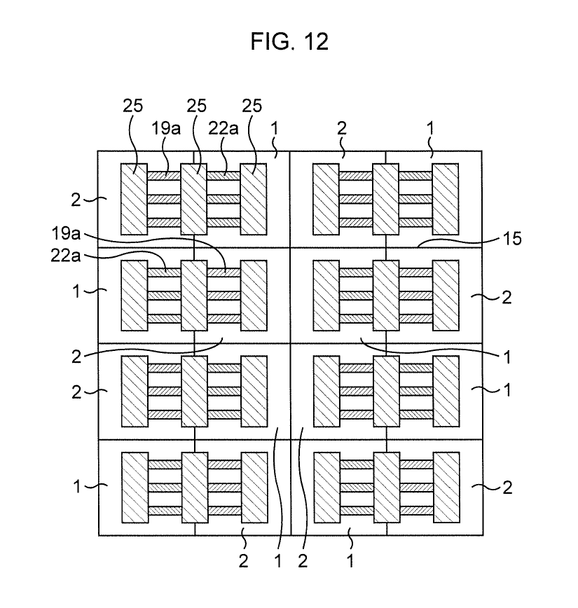

FIG. 12 is a schematic plan view illustrating a layout configuration of the diode formation region of the semiconductor device in this embodiment.

In the diode formation region, a plurality of gate electrodes 25 are arrayed in a matrix form, and the p-type region 22a and the n-type region 19a are alternately arranged in each of the lateral direction and the longitudinal direction in a so-called checkered pattern. In FIG. 12, for convenience, a region including the gate electrode 25 and the p-type region 22a is described as a p-type section 1, and a region including the gate electrode 25 and the n-type region 19a is described as an n-type section 2. Since the sections 1, 2 are alternately arranged in the lateral direction and the longitudinal direction, there are many sites of boundary of p-type and n-type ion implantation, but all of the boundary sites are located in the STI element isolation structure 15, so that the allowable range of mask displacement in manufacture is large.

The first diode D_{A} and the second diode D_{B} share the p-type region 22a and the n-type region 19a. The first diodes D_{A} are arrayed in the lateral direction, and each configured including the gate electrode 25 and the p-type region 22a and the n-type region 19a on both sides of the gate electrode 25. The second diodes D_{B} are arrayed in the longitudinal direction, and each configured including the p-type region 22a and the n-type region 19a and the STI element isolation structure 15 between the p-type region 22a and the n-type region 19a.

A circuit configuration of the semiconductor device according to this embodiment is illustrated in FIG. 13. In FIG. 13, a diode An (n=1, 2, . . . ) is indicated representing the plurality of first diodes D_{A} arrayed in the lateral direction. A diode Bn (n=1, 2, . . . ) is indicated representing the plurality of second diodes D_{B} arrayed in the longitudinal direction. In this embodiment, the diodes An, Bn are connected in parallel. Therefore, when a surge current flows from an I/O terminal, the surge current is prevented from passing through a CMOS transistor (a p-type MOS transistor and an n-type MOS transistor) and passes through two kinds of current paths P1, P2. The current path P1 is a path passing through the diode An, a power rail clamp, and a VSS terminal. The current path P2 is a path passing through the diode Bn, the power rail clamp, and the VSS terminal. This configuration increases the current path as compared with the case where the ESD protection diode is composed of only the gate-type diode or only the STI-type diode as in the prior art, and realizes lowered resistance of the ESD protection diode. Further, alternately arranging the p-type section 1 and the n-type section 2 as in this embodiment can reduce the occupied area of the ESD protection diode as compared with the case of the prior art.

As described above, according to this embodiment, a semiconductor device is realized which is high in reliability including an ESD protection diode capable of sufficiently coping with a large surge current while achieving lowered resistance and reduced occupied area.

### Second Embodiment

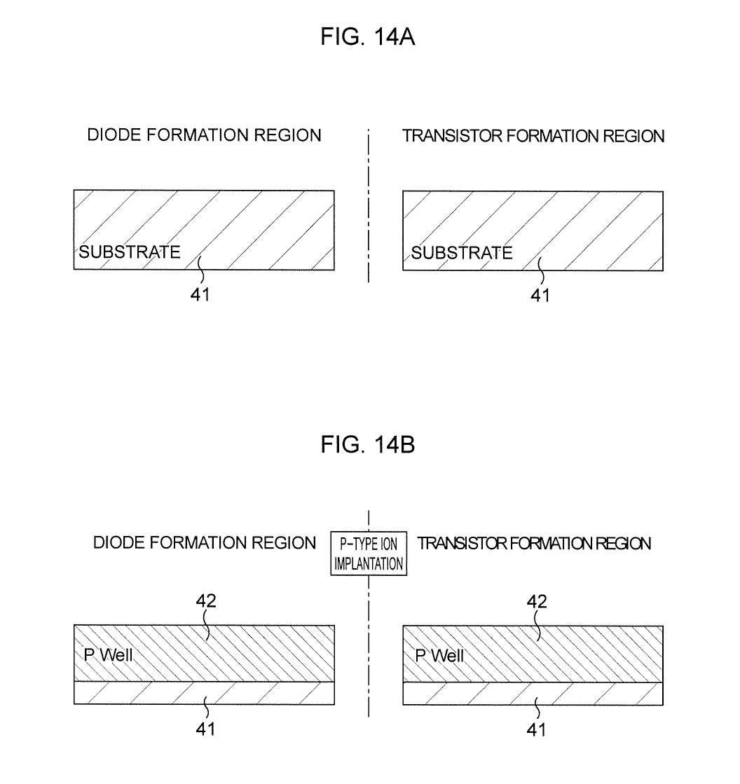

Hereinafter, a second embodiment will be described. In this embodiment, a semiconductor device including an ESD protection diode to which a so-called vertical transistor structure is applied will be disclosed. FIG. 14A to FIG. 22 are schematic views illustrating a method for manufacturing the semiconductor device according to this embodiment.

First, as illustrated in FIG. 14A, for example, a silicon substrate 41 is prepared as a semiconductor substrate. In the following drawings, the left side illustrates a diode formation region and the right side illustrates a transistor formation region.

Subsequently, as illustrated in FIG. 14B, a p-type well 42 is formed.

In more detail, a p-type impurity is ion-implanted into a surface of the silicon substrate 41 to form the p-type well 42 in a surface layer of the silicon substrate 41.

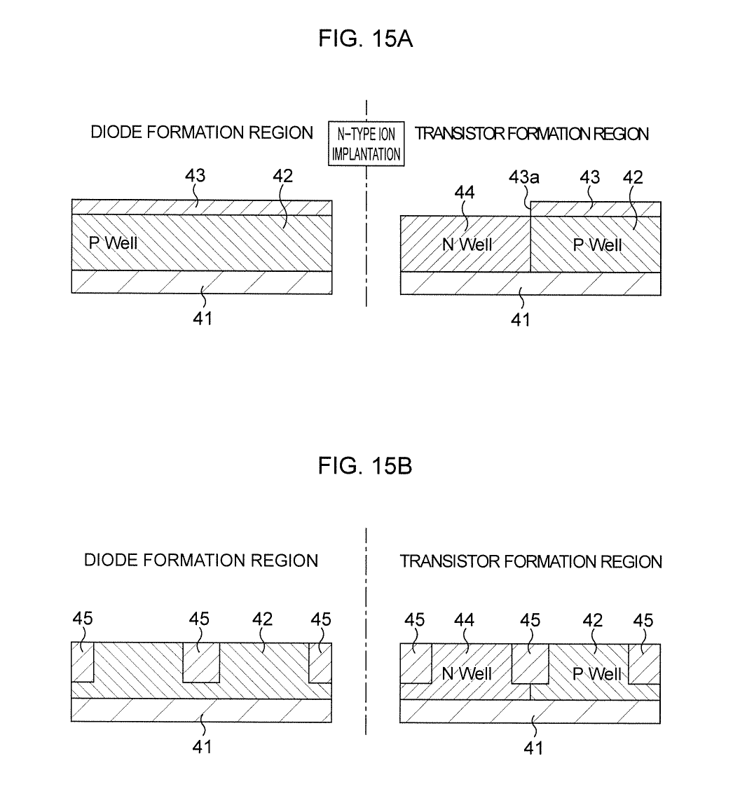

Subsequently, as illustrated in FIG. 15A, an n-type well 44 is formed.

In more detail, first, a resist is applied to the surface of the silicon substrate 41 and processed by lithography. Thus, a resist mask 43 including an opening 43a exposing an n-type well formation region in the transistor formation region is formed on the surface of the silicon substrate 41.

Next, an n-type impurity is ion-implanted to a portion of the silicon substrate 41 exposed from the opening 43a using the resist mask 43. Thus, the n-type well 44 adjacent to the p-type well 42 is formed in the surface layer of the silicon substrate 41 in the transistor formation region. The resist mask 43 is removed by wet treatment or aching.

Subsequently, as illustrated in FIG. 15B, an STI element isolation structure 45 is formed.

In more detail, an element isolation region of the silicon substrate 41 is processed by lithography and dry etching to form a trench in the element isolation region. An insulating film, for example, a silicon oxide film is deposited on the silicon substrate 41 by the CVD method or the like in a manner to be buried in the trench. The deposited silicon oxide film is planarized by etching back, whereby the STI element isolation structure 45 in which the silicon oxide film is buried in the trench in the element isolation region is formed in the surface layer of the silicon substrate 41.

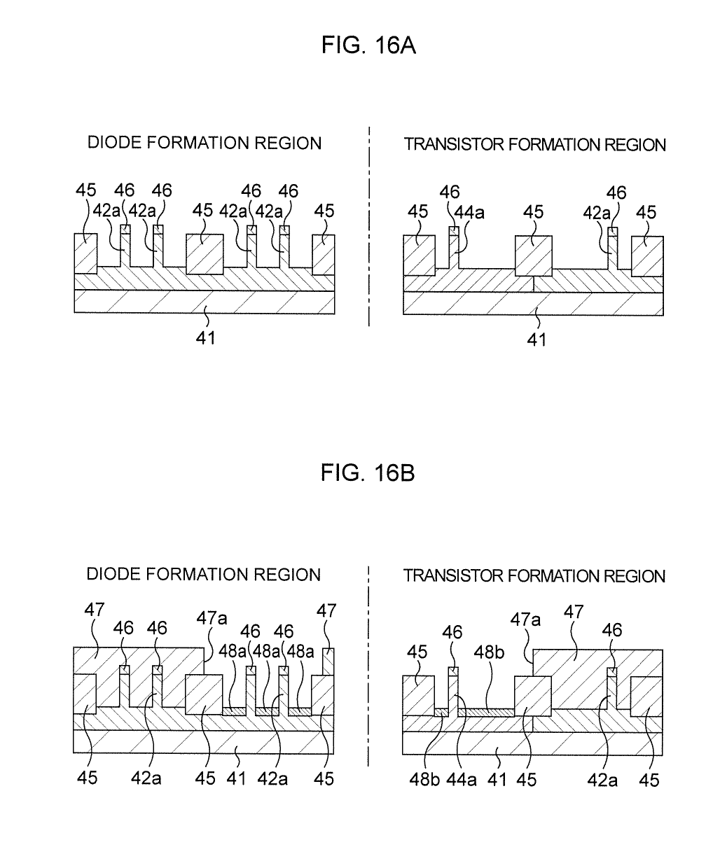

Subsequently, as illustrated in FIG. 16A, the silicon substrate 41 is processed into a shape of columns.

In more detail, a hard mask 46 made of, for example, a silicon nitride film is formed on the silicon substrate 41, and portions of the p-type well 42 and the n-type well 44 of the silicon substrate 41 are subjected to dry etching using the hard mask 46. Thus, the silicon substrate 41 is processed into the shape of columns. A columnar portion of the p-type well 42 is a columnar projection 42a, and a columnar portion of the n-type well 44 is a columnar projection 44a.

Subsequently, as illustrated in FIG. 16B, a p-type region 48a is formed in the diode formation region, and a p-type source/drain region 48b is formed in the transistor formation region.

In more detail, first, a resist is applied to the surface of the silicon substrate 41 and processed by lithography. Thus, a resist mask 47 is formed which includes an opening 47a exposing a formation site for the p-type region around the columnar projection 42a in the diode formation region, and an opening 47a exposing a formation site for the p-type source/drain region around the columnar projection 44a in the transistor formation region.

Next, a p-type impurity is ion-implanted to a portion around the columnar projection 42a exposed from the opening 47a using the resist mask 47. The ion implantation is performed under a condition to achieve a concentration higher than a p-type impurity concentration in the p-type well 42. Thus, the p-type region 48a is formed around the columnar projection 42a in the diode formation region, and the p-type source/drain region 48b is formed around the columnar projection 44a in the transistor formation region. The resist mask 47 is removed by wet treatment or ashing.

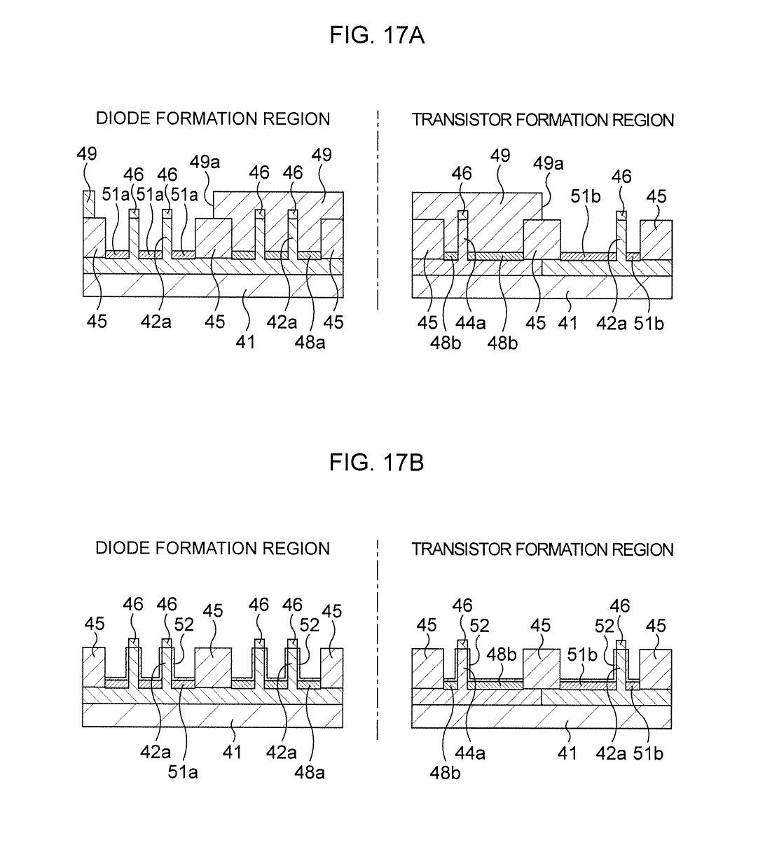

Subsequently, as illustrated in FIG. 17A, an n-type region 51a is formed in the diode formation region, and an n-type source/drain region 51b is formed in the transistor formation region.

In more detail, first, a resist is applied to the surface of the silicon substrate 41 and processed by lithography. Thus, a resist mask 49 is formed which includes an opening 49a exposing a formation site for the n-type region around the columnar projection 42a in the diode formation region, and an opening 49a exposing a formation site for the n-type source/drain region around the columnar projection 42a in the transistor formation region.

Next, an n-type impurity is ion-implanted to a portion around the columnar projection 42a exposed from the opening 49a using the resist mask 49. The ion implantation is performed under a condition to achieve a concentration higher than an n-type impurity concentration in the n-type well 44. Thus, the n-type region 51a is formed around the columnar projection 42a in the diode formation region, and the n-type source/drain region 51b is formed around the columnar projection 42a in the transistor formation region. The resist mask 49 is removed by wet treatment or asking.

Subsequently, as illustrated in FIG. 17B, a gate insulating film 52 is formed.

In more detail, thermal oxidation is performed on the surface of the silicon substrate 41. In this event, the gate insulating film 52 is formed from the side surface of the columnar projection 42a over the surface of the p-type region 48a or the surface of the n-type region 51a in the diode formation region. The gate insulating film 52 is formed from the side surface of the columnar projection 44a over the surface of the p-type source/drain region 48b and from the side surface of the columnar projection 42a over the surface of the n-type source/drain region 51b in the transistor formation region.

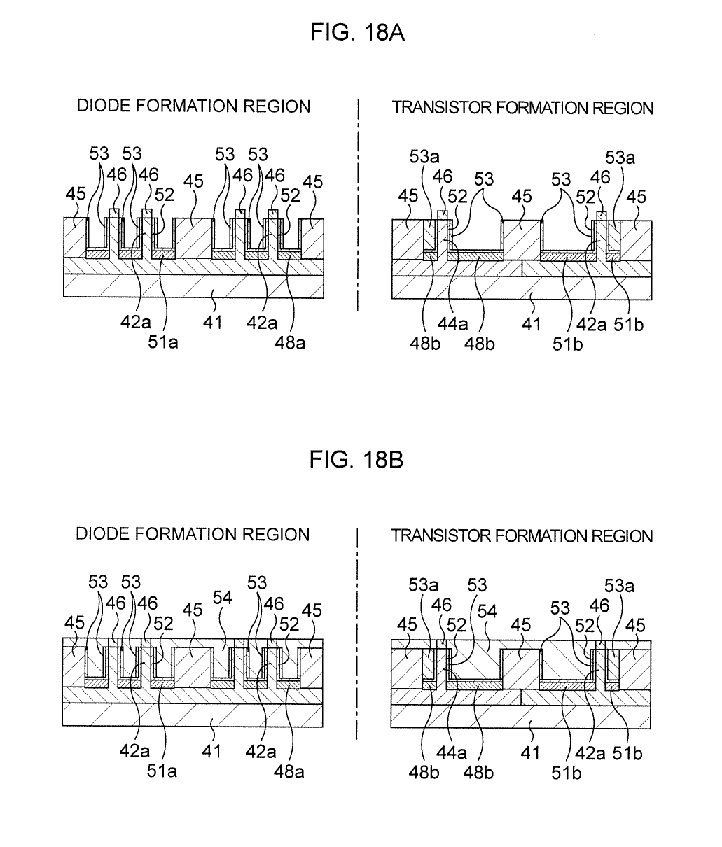

Subsequently, as illustrated in FIG. 18A, a gate insulating film 53 is formed.

In more detail, for example, a polycrystalline silicon film is deposited on the entire surface of the silicon substrate 41 by the CVD method, and the entire surface is etched back. The polycrystalline silicon film remains only on the side surfaces of the columnar projections 42a, 44a via the gate insulating film 52 to form the gate electrode 53. In this event, a polycrystalline silicon film 53a thicker than the gate electrode 53 is left to be buried in the spaces between the side surfaces of the columnar projections 42a, 44a and the STI element isolation structure 45 in the transistor formation region.

Subsequently, as illustrated in FIG. 18B, an interlayer insulating film 54 is formed.

In more detail, an insulating film, for example, a silicon oxide film is deposited on the entire surface of the silicon substrate 41 by the CVD method or the like. The silicon oxide film is planarized by the CMP method until the upper surface of the hard mask 46 is exposed. Thus, an interlayer insulating film 54 from the surface of which the upper surface of the hard mask 46 is exposed, is formed.

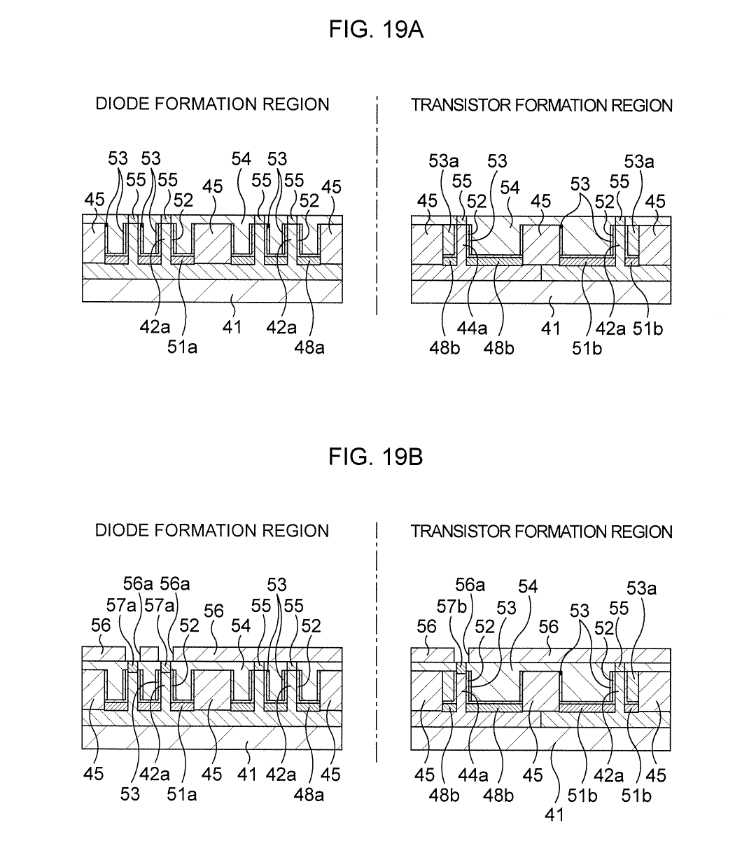

Subsequently, as illustrated in FIG. 19A, a Si layer 55 is formed.

In more detail, first, the hard mask 46 is selectively removed, for example, by wet etching. Thereafter, a semiconductor layer, here, the Si layer 55 is epitaxially grown from the upper surfaces of the columnar projections 42a, 44a exposed under the surface of the interlayer insulating film 54.

Subsequently, as illustrated in FIG. 19B, a p-type region 57a is formed in the diode formation region, and a p-type source/drain region 57b is formed in the transistor formation region.

In more detail, first, a resist is applied to the surface of the interlayer insulating film 54 and processed by lithography. Thus, a resist mask 56 is formed which includes an opening 56a exposing the upper surface of the Si layer 55 on the columnar projection 42a in the diode formation region, and an opening 56a exposing the upper surface of the Si layer 55 on the columnar projection 44a in the transistor formation region.

Next, a p-type impurity is ion-implanted to portions of the upper surfaces of the columnar projections 42a, 44a exposed from the openings 56a using the resist mask 56. Thus, the p-type region 57a is formed in the Si layer 55 in the diode formation region, and the p-type source/drain region 57b is formed in the Si layer 55 in the transistor formation region. The resist mask 56 is removed by wet treatment or ashing.

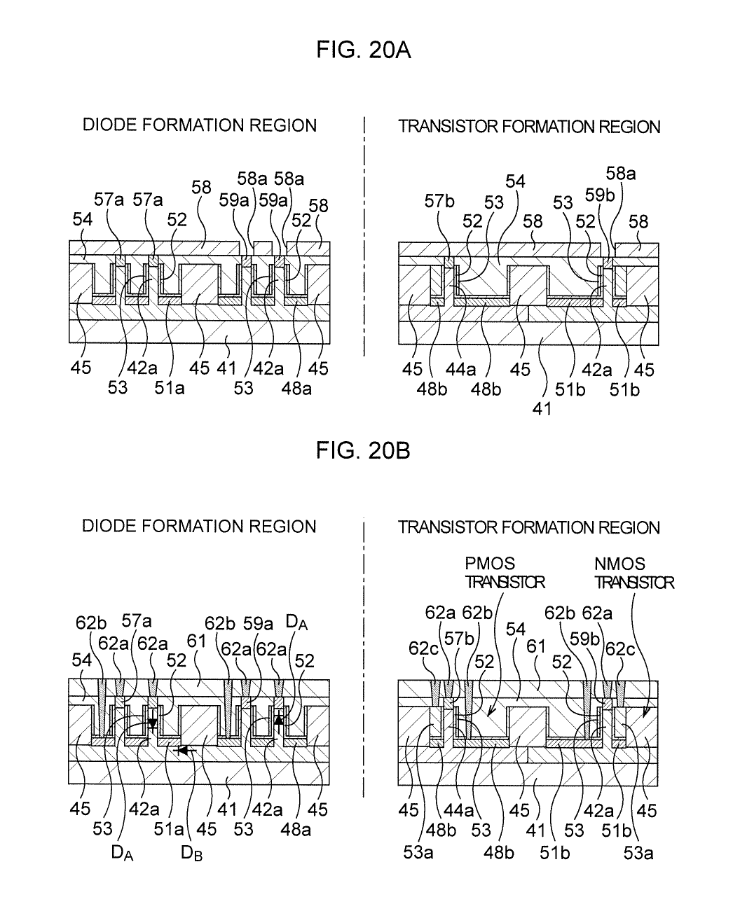

Subsequently, as illustrated in FIG. 20A, an n-type region 59a is formed in the diode formation region, and an n-type source/drain region 59b is formed in the transistor formation region.

In more detail, first, a resist is applied to the surface of the interlayer insulating film 54 and processed by lithography. Thus, a resist mask 58 is formed which includes an opening 58a exposing the upper surface of the Si layer 55 on the columnar projection 42a in each of the diode formation region and the transistor formation region.

Next, an n-type impurity is ion-implanted to the upper surface portion of the columnar projection 42a exposed from the opening 58a using the resist mask 58. Thus, the n-type region 59a is formed in the Si layer 55 in the diode formation region, and the n-type source/drain region 59b is formed in the Si layer 55 in the transistor formation region. The resist mask 58 is removed by wet treatment or ashing.

Subsequently, as illustrated in FIG. 20B, contact plugs 62a to 62c are formed.

In more detail, first, an insulating film, for example, a silicon oxide film is deposited on the interlayer insulating film 54 by the CVD method or the like to form an interlayer insulating film 61.

Next, the gate insulating film 52 and the interlayer insulating films 54, 61 are processed by lithography and dry etching. Thus, in the diode formation region, openings exposing parts of the surfaces of the p-type region 57a and the n-type region 59a are formed in the interlayer insulating film 61, and openings exposing parts of the surfaces of the p-type region 48a and the n-type region 51a are formed in the gate insulating film 52 and the interlayer insulating films 54, 61. In the transistor formation region, openings exposing parts of the surfaces of the p-type region 57b and the n-type region 59b are formed in the interlayer insulating film 61, openings exposing parts of the surfaces of the p-type region 48b and the n-type region 51b are formed in the gate insulating film 52 and the interlayer insulating films 54, 61, and an opening exposing a part of the surface of the polycrystalline silicon film 53a is formed in the interlayer insulating films 54, 61.

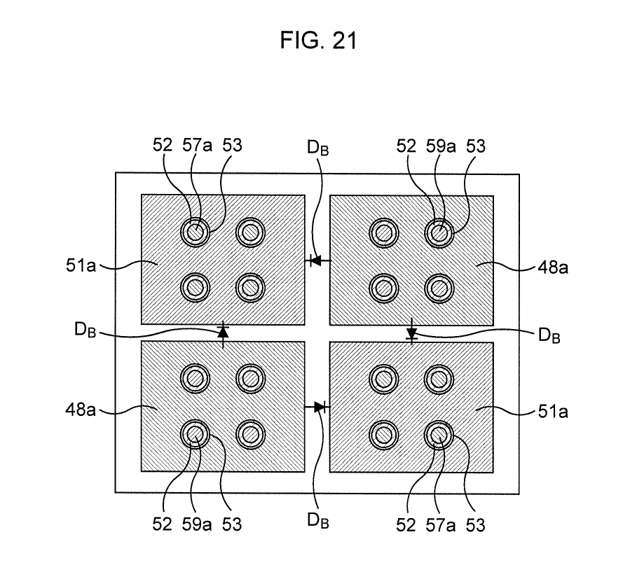

Next, a metal material, for example, tungsten using titanium or titanium nitride as a base is deposited on the interlayer insulating film 61 in a manner to be buried in the openings. The deposited titanium or titanium nitride and tungsten are planarized by the CMP method until the upper surface of the interlayer insulating film 61 is exposed. Thus, the contact plugs 62a connected to the p-type region 57a and the n-type region 59a respectively and the contact plugs 62b connected to the p-type region 48a and the n-type region 51a respectively are formed in the diode formation region. The contact plugs 62a connected to the p-type source/drain region 57b and the n-type source/drain region 59b respectively, the contact plugs 62b connected to the p-type source/drain region 48b and the n-type source/drain region 51b respectively, and the contact plug 62c connected to the polycrystalline silicon film 53a are formed in the transistor formation region. FIG. 21 is a schematic plan view illustrating a layout configuration of the diode formation region of the semiconductor device according to this embodiment. In FIG. 21, the illustration of the interlayer insulating films 54, 61 and the contact plugs 62a to 62c is omitted.

Thereafter, the multilayer wiring structure and the connection pad are formed as in the first embodiment to form the semiconductor device according to this embodiment. The connection pad is arranged above the diode formation region and the transistor formation region in a manner to include the diode formation region and the transistor formation region in a plan view.

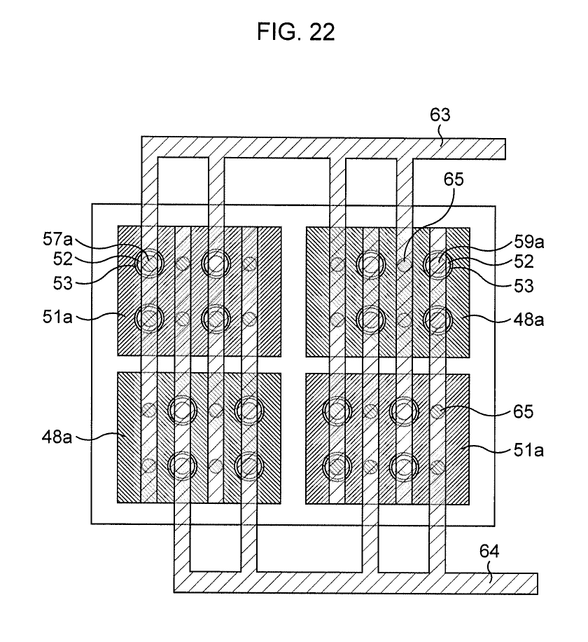

Also in this embodiment, the first wiring layer of the multilayer wiring structure may be formed as in FIG. 22 as in the first embodiment. In this case, the p-type regions 57a and the n-type regions 59a in one row in the lateral direction are laid out to be shifted by a half pitch every other raw. Configuring the layout makes it possible to form wirings 63, 64 in the first wiring layer extending only in one direction (here, the longitudinal direction). More specifically, the wirings 63, 64 extend, connected to a plurality of (two in the illustrated example) p-type region 57a and a plurality of (two in the illustrated example) contact plugs 65 alternately arrayed in the longitudinal direction or connected to a plurality of (two in the illustrated example) n-type region 59a and a plurality of (two in the illustrated example) contact plugs 65 alternately arrayed in the longitudinal direction. This configuration facilitates exposure to light at pattering of the wirings (easy to adopt double patterning).

In this embodiment, a first diode D_{A} and a second diode D_{B} are formed as ESD protection diodes as in FIG. 20B and FIG. 21 in the diode formation region, and they are connected in parallel. In the transistor formation region, a PMOS transistor and an NMOS transistor are formed as in FIG. 20B.

The first diode D_{A} is a gate-type diode including the gate electrode 53 and having a current path formed in the columnar projection 42a near the gate electrode 53. The second diode D_{B} is an STI-type diode including an STI element isolation structure 45 and having a current path formed in the p-type well 42 near the STI element isolation structure 45.

As in FIG. 21, the p-type region 48a and the n-type region 51a are alternately arranged in each of the lateral direction and the longitudinal direction in a so-called checkered pattern in the diode formation region. In one p-type region 48a, a predetermined number of, for example, four columnar projections 42a are formed each having the n-type region 59a formed on the upper surface and having the gate electrode 53 formed on the side surface via the gate insulating film 52. In one n-type region 51a, a predetermined number of, for example, four columnar projections 42a are formed each having the p-type region 57a formed on the upper surface and having the gate electrode 53 formed on the side surface via the gate insulating film 52.

The first diode D_{A} and the second diode D_{B} share the p-type region 48a or the n-type region 51a. The first diodes D_{A} are arrayed in the lateral direction and the longitudinal direction, and each configured including the gate electrode 53, and the p-type region 48a (or the n-type region 51a) around the columnar projection 42a and the n-type region 59a (or the p-type region 57a) on the upper surface. The second diodes D_{B} are arrayed in the lateral direction and the longitudinal direction, and each configured including the p-type region 48a and the n-type region 51a and the STI element isolation structure 45 between the p-type region 48a and the n-type region 51a.

In the semiconductor device of this embodiment, the plurality of first diodes D_{A} being the gate-type diodes and the plurality of second diodes D_{B} being the STI-type diodes are arrayed both in the lateral direction and the longitudinal direction as in FIG. 21 in the diode formation region. The first diodes D_{A} and the second diodes D_{B} are connected in parallel. This configuration forms two kinds of current paths as in FIG. 13 in the first embodiment when a surge current occurs. Therefore, the current path increases as compared with the case where the ESD protection diode is composed of only the gate-type diode or only the STI-type diode as in the prior art, thereby realizing lowered resistance of the ESD protection diode. Further, alternately arranging the p-type region 48a and the n-type region 51a as in this embodiment can reduce the occupied area of the ESD protection diode as compared with the case of the prior art.

As described above, according to this embodiment, a semiconductor device is realized which is high in reliability including an ESD protection diode capable of sufficiently coping with a large surge current while achieving lowered resistance and reduced occupied area.

### Third Embodiment

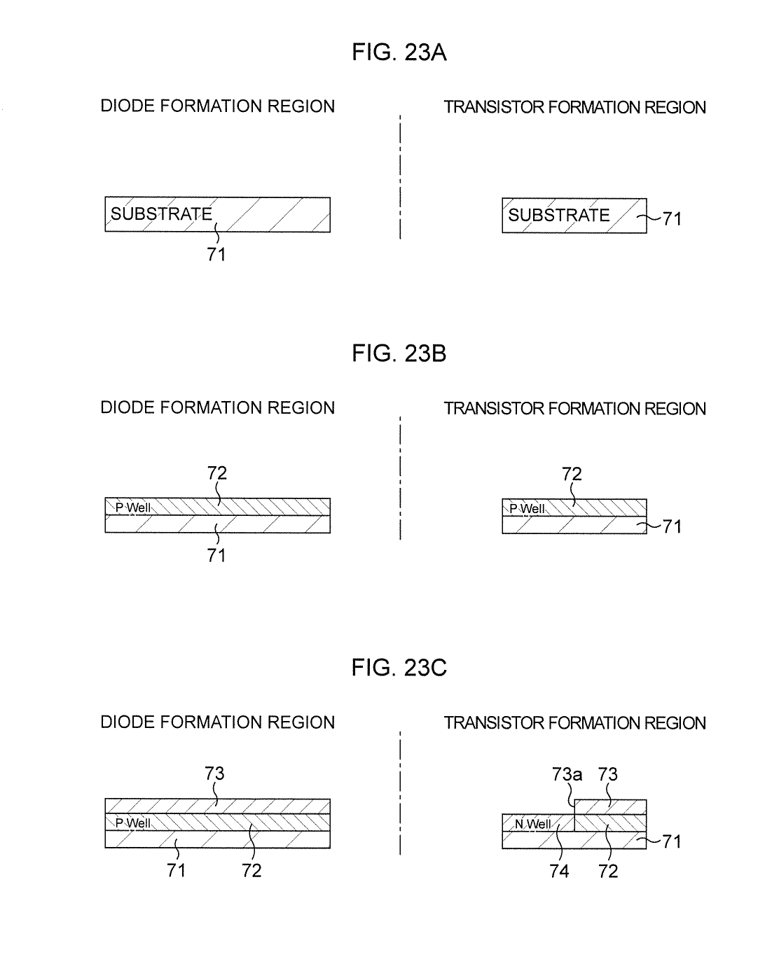

Hereinafter, a third embodiment will be described. In this embodiment, a semiconductor device including an ESD protection diode to which a so-called nanowire structure is applied will be disclosed. FIG. 23A to FIG. 38 are schematic views illustrating a method for manufacturing the semiconductor device according to this embodiment.

First, as illustrated in FIG. 23A, for example, a silicon substrate 71 is prepared as a semiconductor substrate. In the following drawings, the left side illustrates a diode formation region and the right side illustrates a transistor formation region.

Subsequently, as illustrated in FIG. 23B, a p-type well 72 is formed.

In more detail, a p-type impurity is ion-implanted into a surface of the silicon substrate 71 to form the p-type well 72 in a surface layer of the silicon substrate 71.

Subsequently, as illustrated in FIG. 23C, an n-type well 74 is formed.

In more detail, first, a resist is applied to the surface of the silicon substrate 71 and processed by lithography. Thus, a resist mask 73 including an opening 73a exposing an n-type well formation region on the surface of the silicon substrate 71 is formed in the transistor formation region.

Next, an n-type impurity is ion-implanted to a portion of the silicon substrate 71 exposed from the opening 73a using the resist mask 73. Thus, the n-type well 74 adjacent to the p-type well 72 is formed in the surface layer of the silicon substrate 71 in the transistor formation region. The resist mask 73 is removed by wet treatment or ashing.

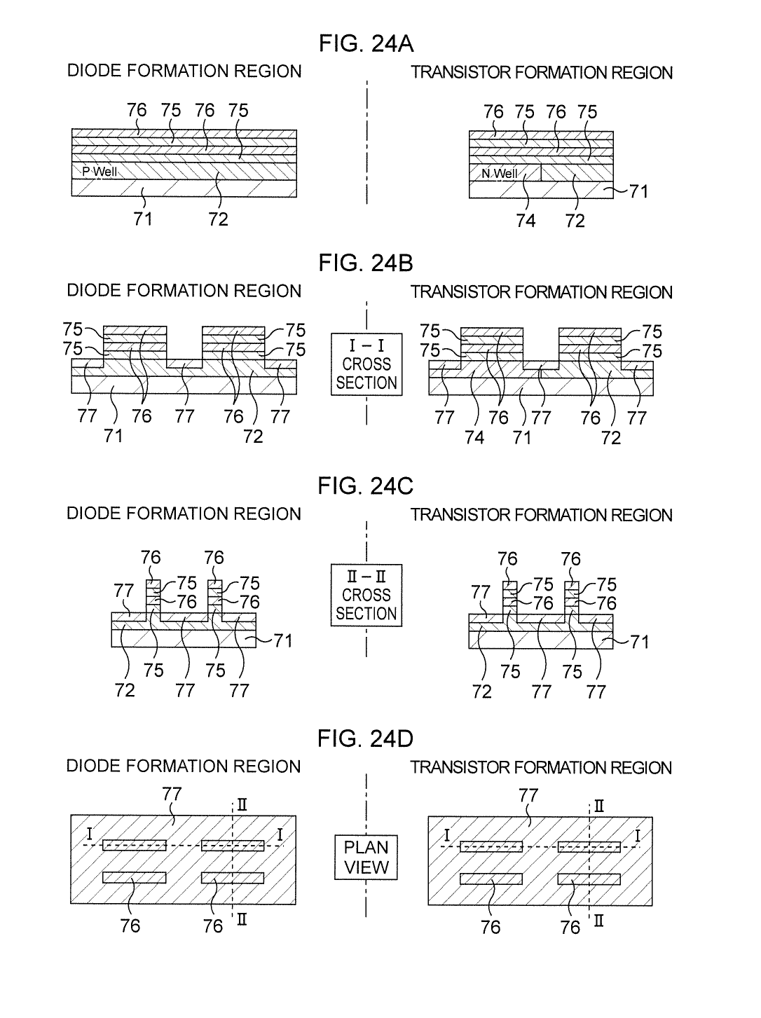

Subsequently, as illustrated in FIG. 24A, a SiGe layer 75 and a Si layer 76 are alternately layered.

In more detail, two kinds of semiconductor layers, here, the SiGe layer 75 and the Si layer 76 are alternately layered a plurality of, for example, two each on the silicon substrate 71. Note that the number of layers to be layered is not limited to two each. For example, the SiGe layer 75 and the Si layer 76 may be layered one each, or may be layered more than two each. Further, the Si layer 76 and the SiGe layer 75 may be layered in this order.

Subsequently, as illustrated in FIG. 24B to FIG. 24D, the silicon substrate 71 is processed into a shape of fins, and then an STI element isolation structure 77 is formed. FIG. 24D is a plan view, FIG. 24B is a cross-sectional view taken along a broken line I-I in FIG. 24D, and FIG. 24C is a cross-sectional view taken along a broken line II-II in FIG. 24D.

In more detail, first, parts of the p-type well 12 and the n-type well 14 of the silicon substrate 71 and the layered structure of the SiGe layer 75 and the Si layer 76 are processed into a shape of fins arrayed in the lateral direction and the longitudinal direction by lithography and dry etching.

Next, an insulating film, for example, a silicon oxide film is deposited on the silicon substrate 71 by the CVD method or the like in a manner to be buried in spaces between the layered structures. By planarizing the deposited silicon oxide film by etching back, the STI element isolation structure 77 is formed in which the silicon oxide film having a predetermined thickness is buried in the space between the layered structures on the silicon substrate 71.

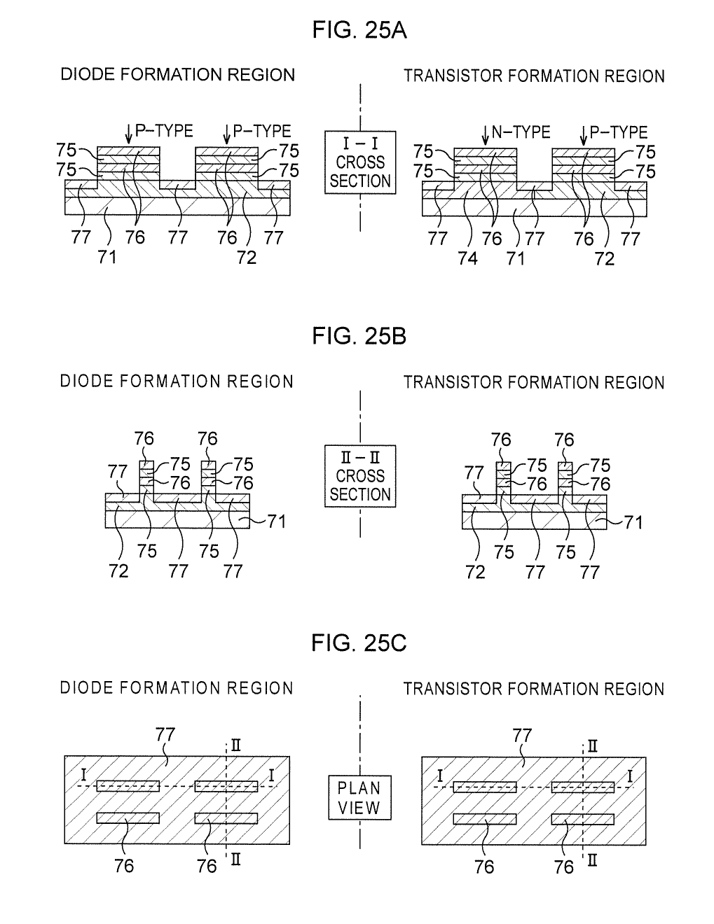

Subsequently, as illustrated in FIG. 25A to FIG. 25C, a p-type impurity and an n-type impurity are ion-implanted to the layered structures of the SiGe layer 75 and the Si layer 76. FIG. 25C is a plan view, FIG. 25A is a cross-sectional view taken along a broken line I-I in FIG. 25C, and FIG. 25B is a cross-sectional view taken along a broken line II-II in FIG. 25C.

In more detail, a resist mask is formed, and the p-type impurity is ion-implanted to the layered structure on the p-type well 72 in the diode formation region. The p-type impurity is ion-implanted to the layered structure on the p-type well 72 and the n-type impurity is ion-implanted to the layered structure on the n-type well 74 in the transistor formation region. The resist mask is removed by wet treatment or ashing.

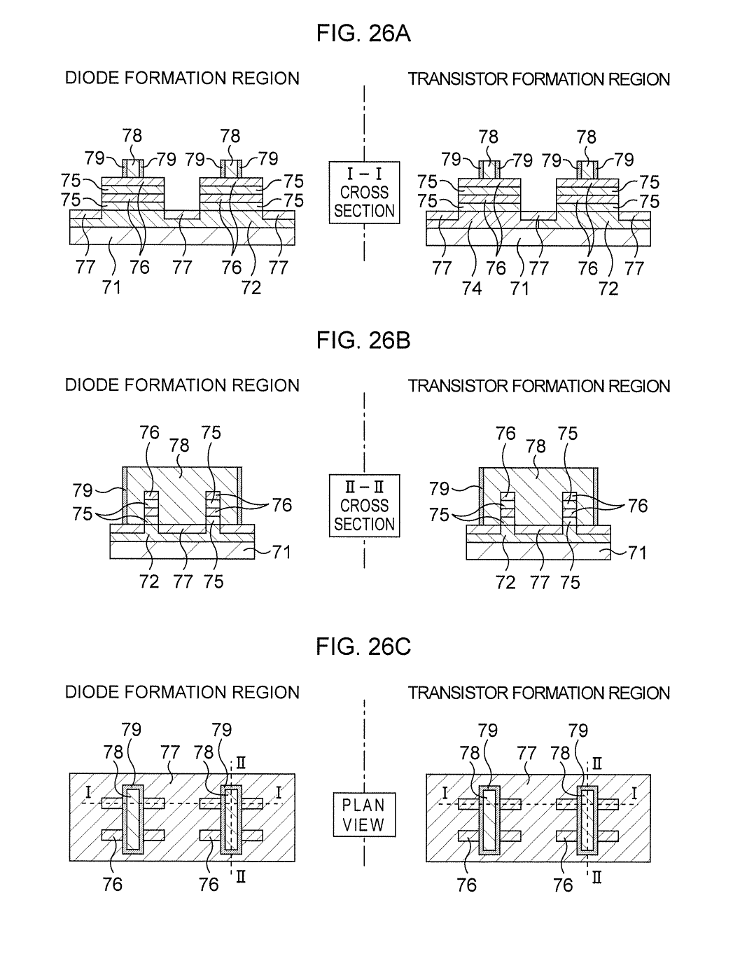

Subsequently, as illustrated in FIG. 26A to FIG. 26C, a sacrificial gate electrode 78 is formed and a side wall 79 is formed on its side surface. FIG. 26C is a plan view, FIG. 26A is a cross-sectional view taken along a broken line I-I in FIG. 26C, and FIG. 26B is a cross-sectional view taken along a broken line II-II in FIG. 26C.

In more detail, first, a polycrystalline silicon film is deposited into a thickness to embed the layered structures on the entire surface of the silicon substrate 71 by the CVD method or the like. The polycrystalline silicon film is processed by lithography and dry etching to remain in a form spreading over two layered structures arrayed in the longitudinal direction. Thus, the sacrificial gate electrode 78 is formed.

Next, an insulating film, for example, a silicon oxide film is deposited on the entire surface of the silicon substrate 71 by the CVD method or the like, and the entire surface of the silicon oxide film is etched back. The silicon oxide film remains only on the side surface of the sacrificial gate electrode 78 to form the side wall 79.

Note that before the formation of the sacrificial gate electrode 78, an insulating film such as a silicon oxide film may be formed on the surface of the layered structure of the SiGe layer 75 and the Si layer 76. The formation of the insulating film can suppress removal of also the layered structure at a later-described step of removing the sacrificial gate electrode 78.

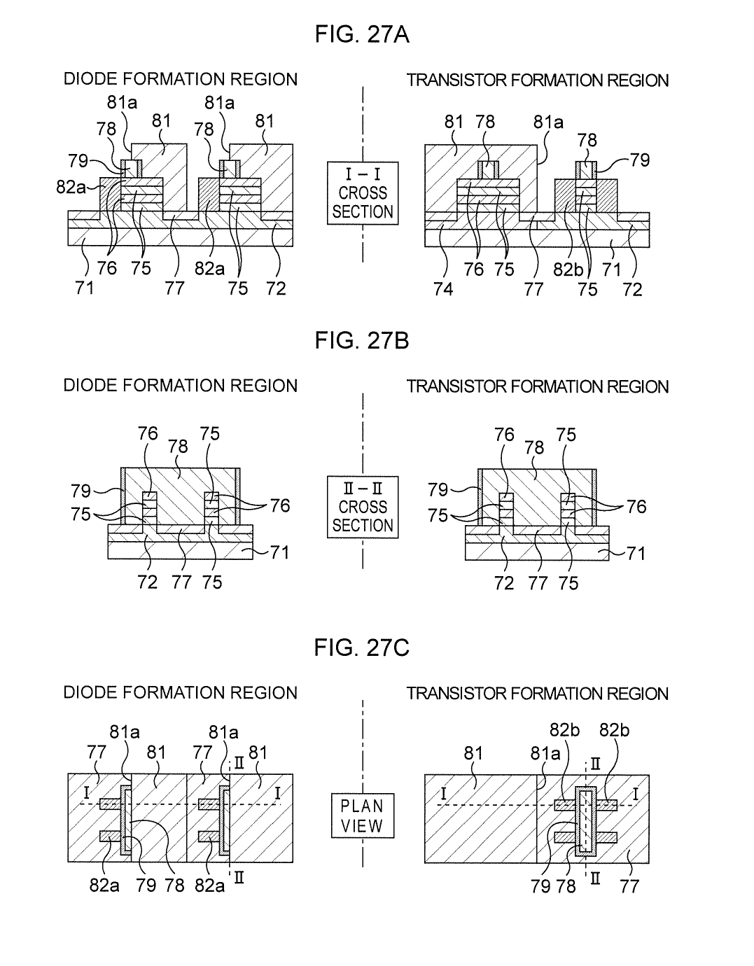

Subsequently, as illustrated in FIG. 27A to FIG. 27C, an n-type region 82a is formed in the diode formation region, and an n-type source/drain region 82b is formed in the transistor formation region. FIG. 27C is a plan view, FIG. 27A is a cross-sectional view taken along a broken line I-I in FIG. 27C, and FIG. 27B is a cross-sectional view taken along a broken line II-II in FIG. 27C.

In more detail, first, a resist is applied to the surface of the silicon substrate 71 and processed by lithography. Thus, a resist mask 81 is formed which includes an opening 81a exposing a formation site for the n-type region in the layered structure in the diode formation region, and an opening 81a exposing a formation site for the n-type source/drain region in the layered structure in the transistor formation region.

Next, an n-type impurity is ion-implanted to a portion of the layered structure exposed from the opening 81a using the resist mask 81. The ion implantation is performed under a condition to achieve a concentration higher than an n-type impurity concentration in the n-type well 74 and the layered structure. Thus, the n-type region 82a is formed in the layered structure in the diode formation region, and the n-type source/drain region 82b is formed in the layered structure in the transistor formation region. The resist mask 82 is removed by wet treatment or asking.

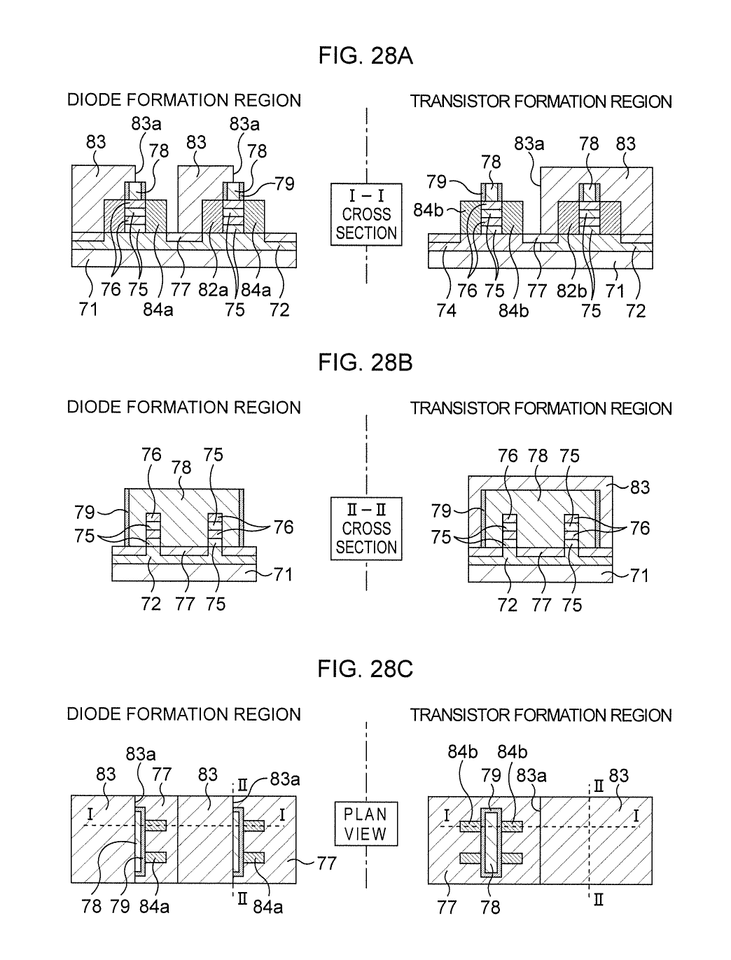

Subsequently, as illustrated in FIG. 28A to FIG. 28C, a p-type region 84a is formed in the diode formation region, and a p-type source/drain region 84b is formed in the transistor formation region. FIG. 28C is a plan view, FIG. 28A is a cross-sectional view taken along a broken line I-I in FIG. 28C, and FIG. 28B is a cross-sectional view taken along a broken line II-II in FIG. 28C.

In more detail, first, a resist is applied to the surface of the silicon substrate 71 and processed by lithography. Thus, a resist mask 83 is formed which includes an opening 83a exposing a formation site for the p-type region in the layered structure in the diode formation region, and an opening 83a exposing a formation site for the p-type source/drain region in the layered structure in the transistor formation region.

Next, a p-type impurity is ion-implanted to a portion of the layered structure exposed from the opening 83a using the resist mask 83. The ion implantation is performed under a condition to achieve a concentration higher than a p-type impurity concentration in the p-type well 72 and the layered structure. Thus, the p-type region 84a is formed in the layered structure in the diode formation region, and the p-type source/drain region 84b is formed in the layered structure in the transistor formation region. The resist mask 83 is removed by wet treatment or ashing.

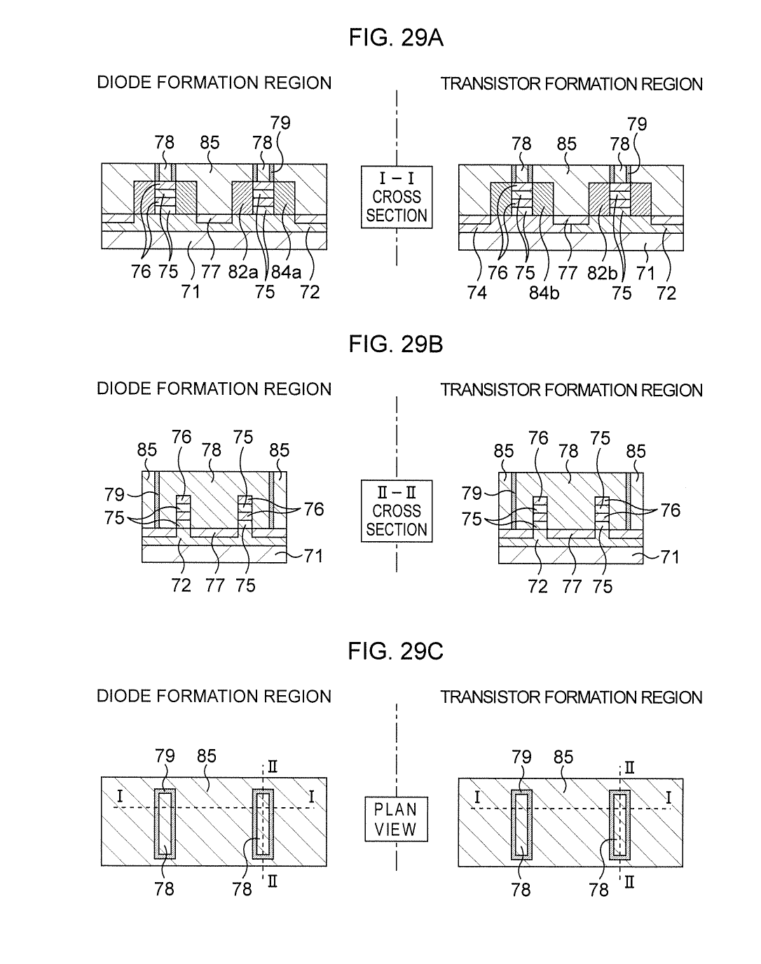

Subsequently, as illustrated in FIG. 29A to FIG. 29C, an interlayer insulating film 85 is formed. FIG. 29C is a plan view, FIG. 29A is a cross-sectional view taken along a broken line I-I in FIG. 29C, and FIG. 29B is a cross-sectional view taken along a broken line II-II in FIG. 29C.

In more detail, an insulating film, for example, a silicon oxide film is deposited on the entire surface of the silicon substrate 71 by the CVD method or the like. The silicon oxide film is planarized by the CMP method until the upper surface of the sacrificial gate electrode 78 is exposed. Thus, the interlayer insulating film 85 from the surface of which the upper surface of the sacrificial gate electrode 78 is exposed, is formed.

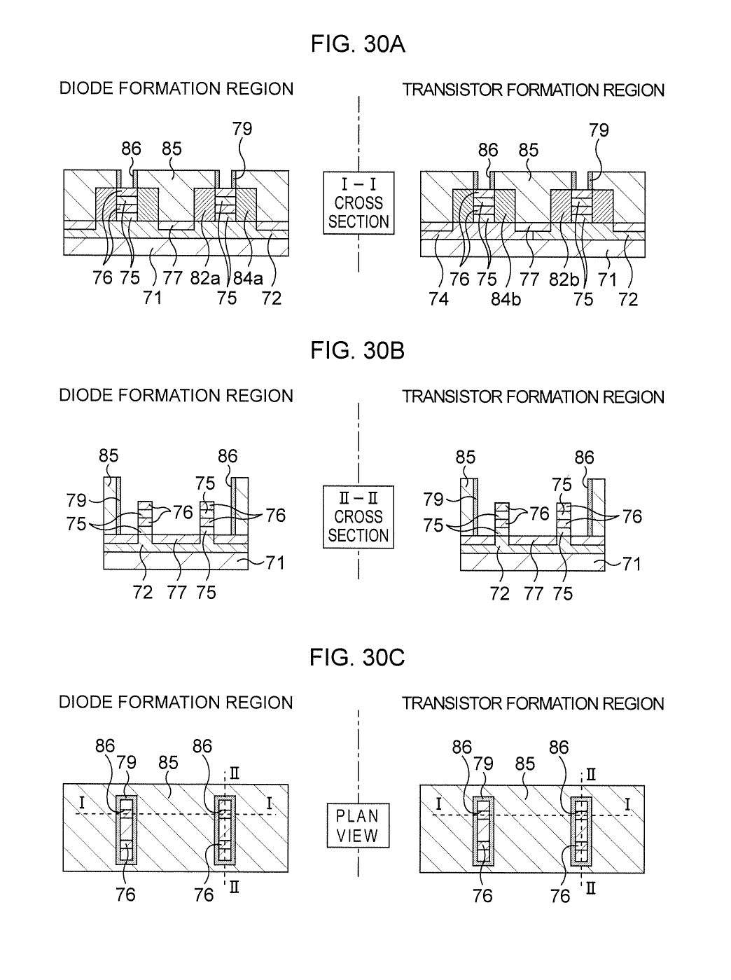

Subsequently, as illustrated in FIG. 30A to FIG. 30C, the sacrificial gate electrode 78 is removed. FIG. 30C is a plan view, FIG. 30A is a cross-sectional view taken along a broken line I-I in FIG. 30C, and FIG. 30B is a cross-sectional view taken along a broken line II-II in FIG. 30C.

In more detail, the sacrificial gate electrode 78 is selectively removed, for example, by wet etching. In this event, a void 86 is formed at a portion where the sacrificial gate electrode 78 has been formed, and the layered structure of the SiGe layer 75 and the Si layer 76 is exposed from the void 86.

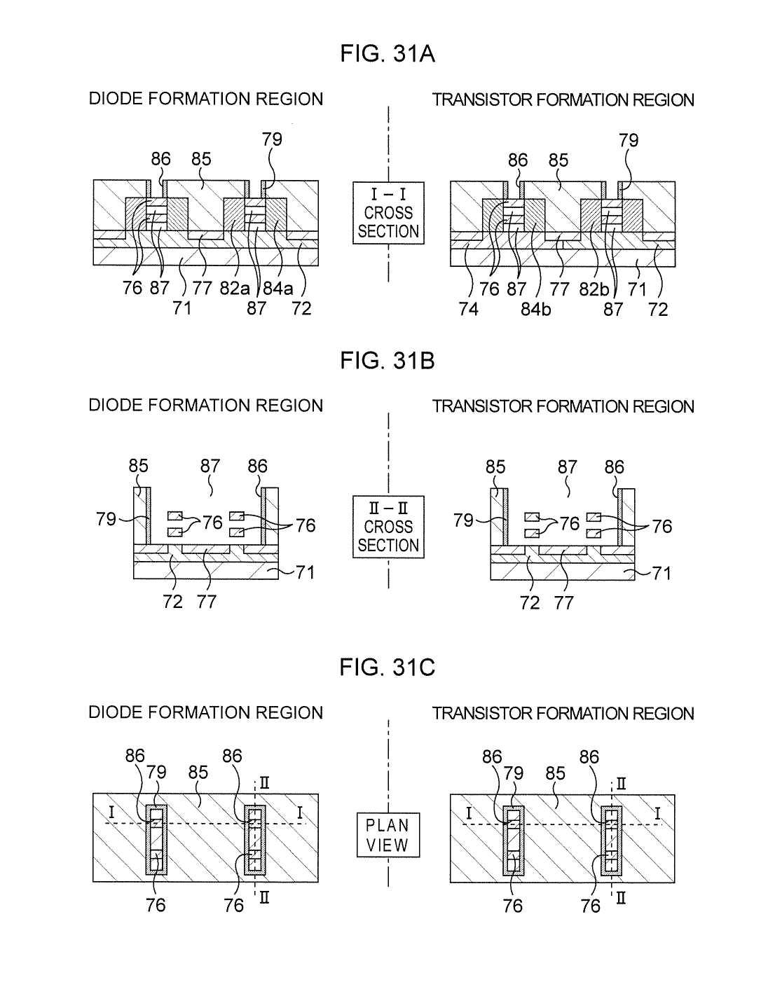

Subsequently, as illustrated in FIG. 31A to FIG. 31C, the SiGe layer 75 or the Si layer 76 of the layered structure is removed. FIG. 31C is a plan view, FIG. 31A is a cross-sectional view taken along a broken line I-I in FIG. 31C, and FIG. 31B is a cross-sectional view taken along a broken line II-II in FIG. 31C.

In more detail, the SiGe layer 75 or the Si layer 76 of the layered structure, for example, the SiGe layer 75 is selectively removed, for example, by wet etching. In this event, a void is formed between the Si layers 76, and communicates with the void 86. A communicated void 87 is illustrated. Note that in the case where the insulating film such as the silicon oxide film has been formed on the surface of the layered structure of the SiGe layer 75 and the Si layer 76 before the formation of the sacrificial gate electrode 78 at the step of FIG. 26A to FIG. 26C, the insulating film is removed before the step of removing the SiGe layer 75.

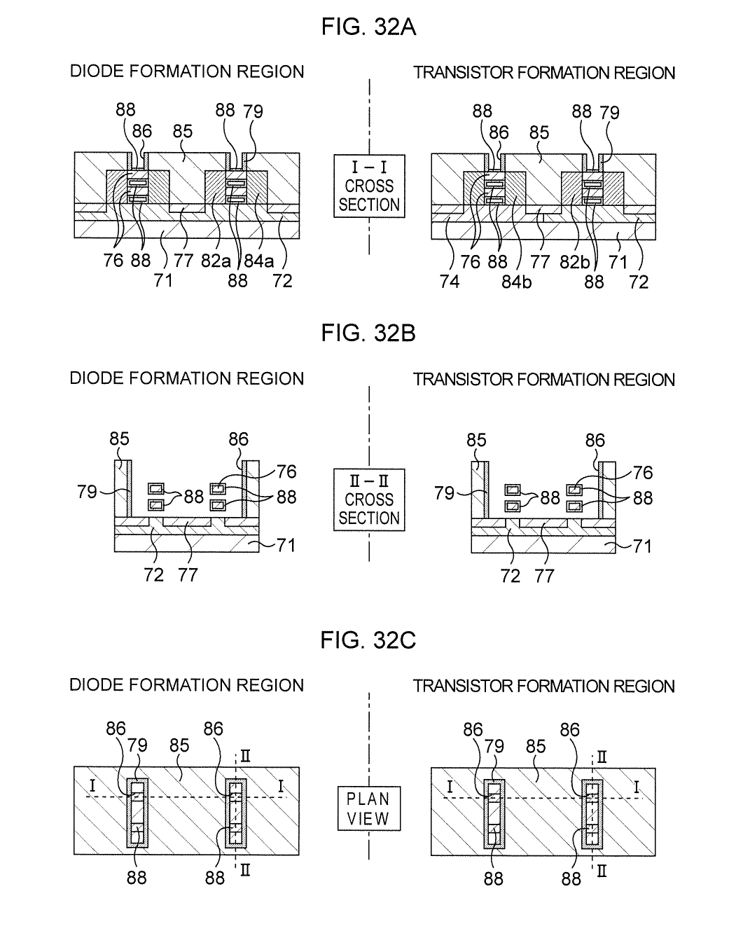

Subsequently, as illustrated in FIG. 32A to FIG. 32C, a gate insulating film 88 is formed. FIG. 32C is a plan view, FIG. 32A is a cross-sectional view taken along a broken line I-I in FIG. 32C, and FIG. 32B is a cross-sectional view taken along a broken line II-II in FIG. 32C.

In more detail, thermal oxidation is performed on the surface of the Si layer 76 exposed in the void 87. Thus, the gate insulating film 88 is formed on the surface of the Si layer 76. Note that instead of forming the gate insulating film 88 by the thermal oxidation, a high dielectric film may be formed as the gate insulating film.

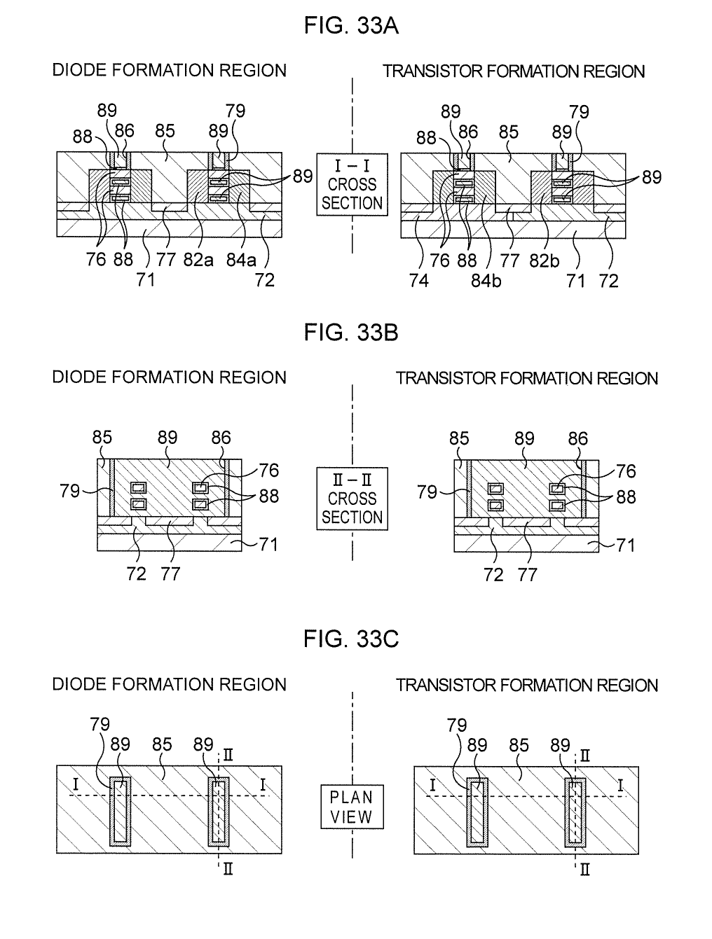

Subsequently, as illustrated in FIG. 33A to FIG. 33C, a gate electrode 89 is formed. FIG. 33C is a plan view, FIG. 33A is a cross-sectional view taken along a broken line I-I in FIG. 33C, and FIG. 33B is a cross-sectional view taken along a broken line II-II in FIG. 33C.

In more detail, for example, a polycrystalline silicon film is deposited as an electrode material on the interlayer insulating film 85 in a manner to be buried in the void 87. The polycrystalline silicon film is planarized by the CMP method until the surface of the interlayer insulating film 85 is exposed. Thus, the gate electrode 89 is formed which is filled in the void 87 and faces the Si layer 76 via the gate insulating film 88. Note that instead of forming the gate electrode 89 of the polycrystalline silicon film, titanium nitride, tantalum nitride or the like may be formed as the material of the gate electrode.

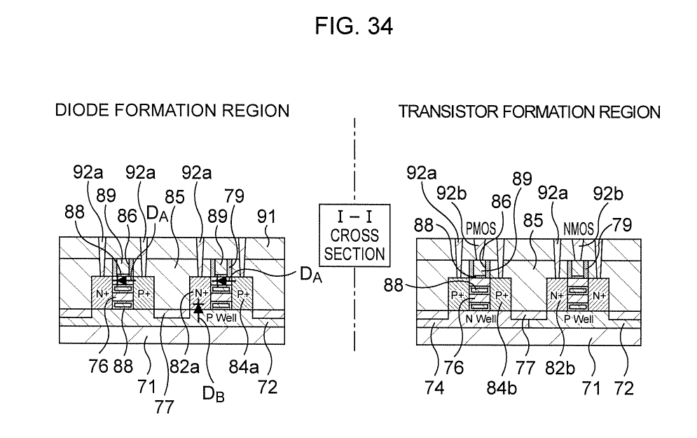

Subsequently, as illustrated in FIG. 34, contact plugs 92a, 92b are formed.

In more detail, first, an insulating film, for example, a silicon oxide film is deposited on the interlayer insulating film 85 by the CVD method or the like to form an interlayer insulating film 91.

Next, the interlayer insulating films 85, 91 are processed by lithography and dry etching. Thus, openings exposing parts of the surfaces of the p-type region 84a and the n-type region 82a are formed in the interlayer insulating films 85, 91 in the diode formation region. Openings exposing parts of the surfaces of the p-type source/drain region 84b and the n-type source/drain region 82b are formed in the interlayer insulating films 85, 91, and an opening exposing a part of the surface of the gate electrode 89 is formed, in the transistor formation region.

Next, a metal material, for example, tungsten using titanium or titanium nitride as a base is deposited on the interlayer insulating film 91 in a manner to be buried in the openings. The deposited titanium or titanium nitride and tungsten are planarized by the CMP method until the upper surface of the interlayer insulating film 91 is exposed. Thus, the contact plugs 92a connected to the p-type region 84a and the n-type region 82a respectively are formed in the diode formation region. The contact plugs 92a connected to the p-type source/drain region 84b and the n-type source/drain region 82b respectively, and the contact plug 92b connected to the gate electrode 89 are formed in the transistor formation region.

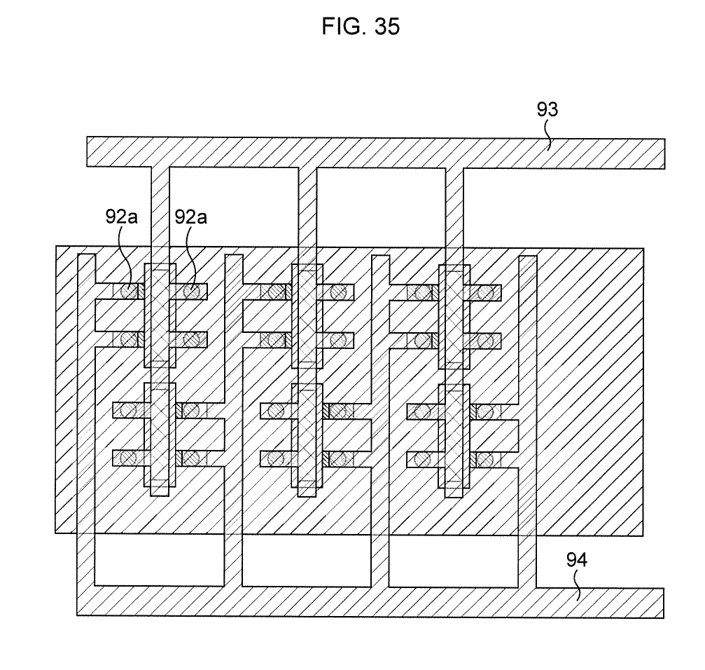

Subsequently, as in the first embodiment, a first wiring layer is formed. Wirings 93, 94 constituting the first wiring layer in the diode formation region are illustrated in FIG. 35. In FIG. 35, the illustration of the interlayer insulating films 85, 91 and so on is omitted.

The wirings 93, 94 are configured by integrally forming a portion extending above the plurality of gate electrodes 89 arrayed in the longitudinal direction and a portion connecting to the contact plug 92a on the p-type region 84a or the contact plug 92a on the n-type region 82a.

Thereafter, the multilayer wiring structure and a connection pad including the first wiring layer are formed as in the first embodiment to form the semiconductor device according to this embodiment. The connection pad is arranged above the diode formation region and the transistor formation region in a manner to include the diode formation region and the transistor formation region in a plan view.

In this embodiment, a first diode D_{A} and a second diode D_{B} are formed as ESD protection diodes as in FIG. 34 in the diode formation region, and they are connected in parallel. In the transistor formation region, a PMOS transistor and an NMOS transistor are formed as in FIG. 34.

The first diode D_{A} is a gate-type diode including the gate electrode 89 and having a current path formed in the Si layer 76 near the gate electrode 89. The second diode D_{B} is an STI-type diode including an STI element isolation structure 77 and having a current path formed in the p-type well 72 near the STI element isolation structure 77.

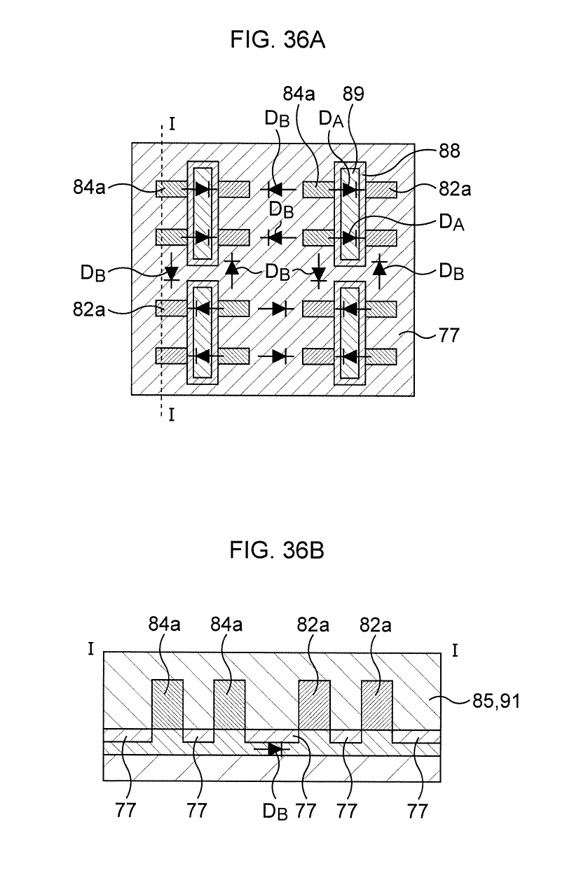

FIG. 36A is a schematic plan view illustrating a layout configuration of the diode formation region of the semiconductor device in this embodiment. FIG. 36B is a schematic cross-sectional view taken along a broken line I-I in FIG. 36A.

In the diode formation region, a plurality of gate electrodes 89 are arrayed in a matrix form, and two p-type region 84a and two n-type region 82a are alternately arranged in each of the lateral direction and the longitudinal direction in a so-called checkered pattern.

The first diode D_{A} and the second diode D_{B} share the p-type region 84a and the n-type region 82a. The first diodes D_{A} are arrayed in the lateral direction, and each configured including the gate electrode 89 and the p-type region 84a and the n-type region 82a on both sides of the gate electrode 89. The second diodes D_{B} are arrayed in the lateral direction and the longitudinal direction, and each configured including the p-type region 84a and the n-type region 82a and the STI element isolation structure 77 between the p-type region 84a and the n-type region 82a.

In the semiconductor device of this embodiment, a plurality of the first diodes D_{A} being the gate-type diodes are formed in the lateral direction and a plurality of the second diodes D_{B} being the STI-type diodes are formed in the lateral direction and the longitudinal direction, as described above in the diode formation region. The first diodes D_{A} and the second diodes D_{B} are connected in parallel. This configuration forms two kinds of current paths when a surge current occurs as in FIG. 13 in the first embodiment. Therefore, the current path increases as compared with the case where the ESD protection diode is composed of only the gate-type diode or only the STI-type diode as in the prior art, thereby realizing lowered resistance of the ESD protection diode. Further, alternately arranging the p-type region 84a and the n-type region 82a as in this embodiment can reduce the occupied area of the ESD protection diode as compared with the case of the prior art.

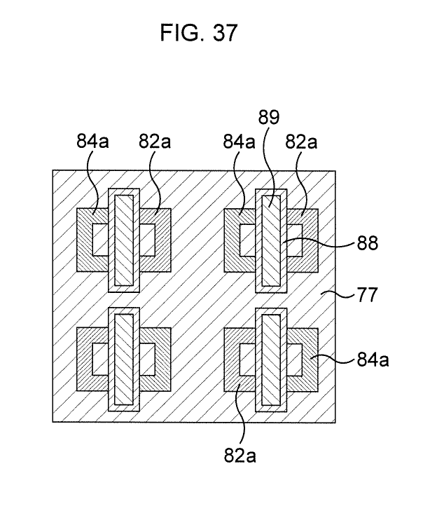

The layout of the diode formation region of the semiconductor device in this embodiment may be configured, for example, as in FIG. 37 in place of the layout in FIG. 36A. In FIG. 37, each of two adjacent n-type regions 84a and two adjacent n-type regions 82a are connected to be integrally formed. This configuration increases the region of the second diode being the STI-type diode, thereby realizing further lowered resistance. Further, since the areas of the p-type region 84a and the n-type region 82a increase, thereby facilitating the connection of the contact plugs.

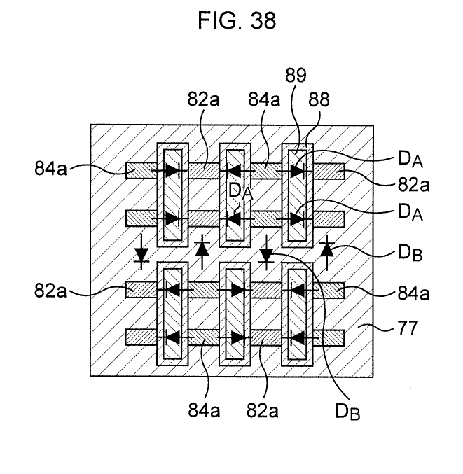

Besides, the layout of the diode formation region of the semiconductor device in this embodiment may be configured, for example, as in FIG. 38. In FIG. 38, . . . the p-type region 84a, the gate electrode 89, the n-type region 82a, the gate electrode 89 . . . are formed to be adjacent in the lateral direction. A plurality of the first diodes D_{A} being the gate-type diodes are formed in the lateral direction, and a plurality of the second diodes D_{B} being the STI-type diodes are formed in the longitudinal direction. With this configuration, a plurality of the gate electrodes 89 can be arrayed at regular intervals and with high density.

As described above, according to this embodiment, a semiconductor device is realized which is high in reliability including an ESD protection diode capable of sufficiently coping with a large surge current while achieving lowered resistance and reduced occupied area.

It should be noted that the above embodiments merely illustrate concrete examples of implementing the present invention, and the technical scope of the present invention is not to be construed in a restrictive manner by these embodiments. That is, the present invention may be implemented in various forms without departing from the technical spirit or main features thereof.

The above aspect realizes a semiconductor device high in reliability including a diode capable of sufficiently coping with a large surge current while achieving lowered resistance and reduced occupied area.

One aspect of the semiconductor device is a semiconductor device high in reliability including an ESD protection diode, capable of surely preventing electrostatic breakdown even if a large surge current occurs while achieving lowered resistance and reduced occupied area of the ESD protection diode.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a semiconductor substrate;
a gate;
a first insulating film in contact with the gate and a first portion of the semiconductor substrate; a second insulating film formed in the semiconductor substrate and in contact with a second portion of the semiconductor substrate;
a plurality of first diodes, each of the first diodes including the first portion of the semiconductor substrate; and
a plurality of second diodes, each of the second diodes including the second portion of the semiconductor substrate, wherein:
the plurality of first diodes are arrayed in a first direction in a plan view;
the plurality of second diodes are arrayed in a second direction different from the first direction in a plan view; and
the first diode and the second diode are electrically connected in parallel.

2. A semiconductor device comprising:
a semiconductor substrate;
a gate;
a first insulating film in contact with the gate and a first portion of the semiconductor substrate;
a second insulating film formed in the semiconductor substrate and in contact with a second portion of the semiconductor substrate;
a plurality of first diodes, each of the first diodes including the first portion of the semiconductor layer; and
a plurality of second diodes, each of the second diodes including the second portion of the semiconductor substrate, wherein:
the plurality of first diodes are arrayed in a first direction in a plan view;
the plurality of second diodes are arrayed in the first direction and in a second direction different from the first direction in a plan view; and
the first diode and the second diode are electrically connected in parallel.

3. The semiconductor device according to claim 1, wherein
the semiconductor substrate includes a first fin and a second fin extending in the first direction and arranged side by side in the second direction,
the first fin includes a first region of a first conductivity type,
the first fin includes a second region of a second conductivity type different from the first conductivity type,
the second fin includes a third region of the second conductivity type,
one of the plurality of first diodes includes the first region and the second region, and
one of the plurality of second diodes includes the first region and the third region.

4. The semiconductor device according to claim 3, wherein
the second fin includes a fourth region of the first conductivity type,
one of the plurality of first diodes includes the third region and the fourth region, and
one of the plurality of second diodes includes the second region and the fourth region.

5. The semiconductor device according to claim 4, wherein
the first fin includes a plurality of the first regions and a plurality of the second regions,
the second fin includes a plurality of the third regions and a plurality of the fourth regions,
the first region and the second region are alternately arranged in the first direction in the first fin, and
the third region and the fourth region are alternately arranged in the first direction in the second fin.

6. The semiconductor device according to claim 3, further comprising:
a first group includes a plurality of the first fins; and
a second group includes a plurality of the second fins and arranged side by side with the first group in the second direction.

7. The semiconductor device according to claim 3, further comprising:
a well formed in the semiconductor substrate,
wherein
the well includes a part located under the second insulating film, and
the second diode includes the well.

8. The semiconductor device according to claim 3, further comprising:
a plurality of first wirings formed on the first diode and the second diode, electrically connecting the first region and the fourth region, and each extending in the second direction; and
a plurality of second wirings formed on the first diode and the second diode, electrically connecting the second region and the third region, and each extending in the second direction.

9. The semiconductor device according to claim 1, wherein:
the semiconductor substrate includes a wire-shaped portion; and
the first diode includes the wire-shaped portion.

10. The semiconductor device according to claim 1, wherein:
the first diode and the second diode share a region of a first conductivity type and a region of a second conductivity type different from the first conductivity type; and
the region of the first conductivity type and the region of the second conductivity type are alternately arranged in each of the first direction and the second direction.

11. The semiconductor device according to claim 10, wherein:
a part of the region of the first conductivity type and a part of the region of the second conductivity type are alternately arranged in the second direction.

12. The semiconductor device according to claim 11, wherein
the region of the first conductivity type and the region of the second conductivity type are connected only by the wiring extending in the first direction or the second direction.

13. A semiconductor device comprising:
a semiconductor substrate;
a gate;
a first insulating film in contact with the gate and a first portion of the semiconductor substrate;
a second insulating film formed in the semiconductor layer and in contact with a second portion of the semiconductor substrate;
a plurality of first diodes, each of the first diodes including the first portion of the semiconductor substrate;
a plurality of second diodes, each of the second diodes including the second portion of the semiconductor substrate;
a first region of a first conductivity type;
a second region of a second conductivity type different from the first conductivity type, located above the first region; and
a third region of the second conductivity type; and
a fourth region of the first conductivity type, located above the third region, wherein:
one of the plurality of first diodes includes the first region and the second region;
another of the plurality of first diodes includes the third region and the fourth region;
the second diode includes the first region and the third region; and
the first diode and the second diode are electrically connected in parallel.

14. The semiconductor device according to claim 1, further comprising:
a diode formation region where the first diode and the second diode are formed, and a transistor formation region where a transistor is formed, wherein
a connection pad is provided above the diode formation region and the transistor formation region, and the diode formation region and the transistor formation region are included in the connection pad in a plan view.
